(19) United States
(12) Patent Application Publication
(10) Pub. No.: US 2022/0319463 A1
(43) Pub. Date: Oct. 6, 2022

(54) Composite Device And Driving Method Of Electronic Device

(71) Applicant: Semiconductor Energy Laboratory Co., Ltd., Kanagawa-ken (JP)

(72) Inventors: Shunpei Yamazaki, Setagaya, Tokyo (JP); Koji KUSUNOKI, Isehara, Kanagawa (JP); Daisuke KUBOTA, Atsugi, Kanagawa (JP)

(73) Assignee: Semiconductor Energy Laboratory Co., Ltd., Kanagawa-ken (JP)

(21) Appl. No.: 17/607,948

(22) PCT Filed: Apr. 27, 2020
(86) PCT No.: PCT/IB2020/053909

§ 371 Date: Nov. 1, 2021

(30) Foreign Application Priority Data
May 10, 2019 (JP) 2019-089925

(51) Int. Cl. G09G 3/36; G06V 40/16; G09G 3/3275; G09G 3/3233

(52) U.S. Cl. CPC G09G 3/3688; G06V 40/166; G09G 3/3275; G09G 3/3233; G09G 2360/144; G09G 2354/00; G09G 2330/023; G09G 2320/0626; G09G 2310/027; G09G 2310/0291; G09G 2310/0289; G09G 3/2007

(57) ABSTRACT

A driving method of an electronic device including a display unit, an imaging unit, and an illuminance sensing unit, the method comprising a first step of detecting that a user sees the display unit by the imaging unit; a second step of measuring external illuminance by the illuminance sensing unit when the user sees the display unit; a third step of determining from the value of the measured external illuminance whether display luminance is to be corrected; a fourth step of displaying an image with a predetermined luminance in the case where the display luminance is determined not to be corrected in the third step; a fifth step of determining a correction value when the display luminance is determined to be corrected in the third step; and a sixth step of displaying an image with a corrected luminance based on the correction value determined in the fifth step.

### TECHNICAL FIELD

One embodiment of the present invention relates to a display device, an electronic device including the display device, and a driving method thereof.

Note that one embodiment of the present invention is not limited to the above technical field. Examples of the technical field of one embodiment of the present invention disclosed in this specification and the like include a semiconductor device, a display device, a light-emitting device, a power storage device, a memory device, an electronic device, a lighting device, an input device, an input/output device, a driving method thereof, and a manufacturing method thereof. A semiconductor device generally means a device that can function by utilizing semiconductor characteristics.

### BACKGROUND ART

In recent years, display devices included in cellular phones such as smartphones, tablet information terminals, laptop PCs (personal computers), portable game consoles, and the like have undergone various improvements. For example, display devices have been developed aiming for higher resolution, higher color reproducibility, a smaller driver circuit, lower power consumption, and the like.

For example, a technique for employing a transistor whose channel formation region contains a metal oxide as a switching element included in a pixel circuit of a display device can be given. In particular, an In—Ga—Zn-based oxide can be used as the metal oxide. Patent Document 1 discloses an invention where a transistor whose channel formation region contains an In—Ga—Zn-based oxide is used in a pixel circuit of a display device.

For another example, Patent Document 2 discloses an invention of a source driver IC of a display device including a light-emitting element, which uses a multi-tone linear digital-analog converter circuit to display a multi-tone image.

### REFERENCE

### Patent Document

[Patent Document 1] Japanese Published Patent Application No. 2010-156963

[Patent Document 2] U.S. Pat. No. 8,462,145

### SUMMARY OF THE INVENTION

### Problems to be Solved by the Invention

Portable information terminal devices such as mobile phones, smart phones, and tablet terminals are employed in a variety of environments. For example, in an environment with high illuminance of external light, an image displayed on a screen is difficult to see. In contrast, a user feels glare when seeing high-luminance display in an environment with low illuminance of external light. The user therefore needs to make the display luminance optimal for a usage environment.

An object of one embodiment of the present invention is to provide a display device allowing a user to see an image with an optimal luminance in any usage environment. Another object is to provide a display device allowing an image with an optimal luminance to be displayed without user's consciousness.

As a condition for displaying a high-quality image, a display device needs to have, for example, a high resolution, multi tones, and a wide color gamut. For example, in a display device including a liquid crystal element or a light-emitting element such as an organic EL (Electro Luminescence) element, a source driver circuit needs to be suitably designed to realize multi-tone images.

To handle multi-tone image data, however, the resolving power of a digital-analog converter circuit included in a source driver circuit needs to be high; in the case where a digital-analog converter circuit having a high resolving power is designed, the area of the digital-analog converter circuit increases.

In addition, a circuit unit that handles analog signals, such as a digital-analog converter circuit included in a source driver circuit, needs a higher power supply voltage than a circuit unit that generates digital signals. Thus, it is difficult to reduce the power consumption of the source driver circuit. Furthermore, a device on which a display panel is mounted needs a circuit that generates at least two kinds of power supply voltages.

An object of one embodiment of the present invention is to reduce the power consumption of a display device. Another object is to reduce the power consumption of a driver circuit in a display device. Another object is to provide a display device including a source driver circuit that can be driven with a single power supply voltage. Another object is to reduce the power consumption of a device including a display device. Another object is to simplify the structure of a display device, a driver circuit, or a device including a display device.

Another object is to provide a pixel circuit capable of generating multi-tone image data (the pixel circuit is referred to as a semiconductor device in this specification and the like). Another object is to provide a display device including the semiconductor device. Another object is to provide an electronic device including the display device.

Another object is to provide a display device including a source driver circuit with a small circuit area. Another object is to provide a display device including a source driver circuit having low power consumption.

Note that the description of these objects does not preclude the existence of other objects. One embodiment of the present invention does not have to achieve all these objects. Objects other than these can be derived from the description of the specification, the drawings, the claims, and the like.

### Means for Solving the Problems

One embodiment of the present invention is a composite device including a display unit, an imaging unit, and an illuminance sensing unit. The composite device has a function of detecting that a user sees the display unit by the imaging unit, a function of measuring external illuminance by the illuminance sensing unit in the case where the user sees the display unit, and a function of determining a correction value of a display luminance in accordance with the value of the measured external illuminance and displaying an image with a luminance based on the correction value.

The aforementioned composite device preferably has a function of sensing part or the whole of a user's face by the imaging unit, a function of estimating a user's emotion from data of the part or the whole of the face sensed, and a function of supplying data to the user by the display unit in accordance with the estimated emotion.

The aforementioned composite device preferably includes an audio output unit. In that case, the composite device preferably has a function of supplying data to the user with sound by the audio output unit.

One embodiment of the present invention is a driving method of an electronic device including a display unit, an imaging unit, and an illuminance sensing unit, which has the following steps: a first step of detecting that a user sees the display unit by the imaging unit; a second step of measuring external illuminance by the illuminance sensing unit when the user sees the display unit; a third step of determining from the value of the measured external illuminance whether display luminance is to be corrected; a fourth step of displaying an image with a predetermined luminance in the case where the display luminance is determined not to be corrected in the third step; a fifth step of determining a correction value in the case where the display luminance is determined to be corrected in the third step; and a sixth step of displaying an image with a corrected luminance based on the correction value determined in the fifth step.

One embodiment of the present invention is a program for executing the following operations in hardware including a display unit, an imaging unit, and an illuminance sensing unit, which has the following steps: a first step of detecting that a user sees the display unit by the imaging unit; a second step of measuring external illuminance by the illuminance sensing unit when the user sees the display unit; a third step of determining from the value of the measured external illuminance whether the luminance of the display unit is to be corrected; a fourth step of displaying an image with a predetermined luminance in the case where the luminance of the display unit is determined not to be corrected in the third step; a fifth step of determining a correction value in the case where the luminance of the display unit is determined to be corrected in the third step; and a sixth step of displaying an image with a corrected luminance based on the correction value determined in the fifth step.

The aforementioned driving method or program preferably has a seventh step of turning off display on the display unit in the case where the user does not see the display unit in the first step.

In the aforementioned driving method, the display unit preferably includes a display device. The display device includes a pixel including a display element. The pixel has a function of retaining a first voltage based on an input first pulse signal and a function of driving the display element with a third voltage that is obtained by adding the first voltage and a second voltage based on an input second pulse signal. The first pulse signal is determined in accordance with the correction value.

In the above, preferably, the display element is a light-emitting element and the light-emitting element emits light with a luminance based on the third voltage. In that case, the light-emitting element is preferably an organic EL element or a light-emitting diode.

Alternatively, in the above, preferably, the display element is a liquid crystal element and the alignment of the liquid crystal in the liquid crystal element changes with the third voltage.

In the above, a first driver circuit supplying the first pulse signal is preferably included. In that case, a first power supply voltage for generating the first pulse signal in the first driver circuit is preferably lower than the maximum value of the third voltage.

### Effect of the Invention

According to one embodiment of the present invention, a display device allowing a user to see an image with an optimal luminance in any usage environment can be provided. A display device allowing an image with an optimal luminance to be displayed without user's consciousness can be provided.

According to one embodiment of the present invention, the power consumption of a display device can be reduced. The power consumption of a driver circuit in a display device can be reduced. A display device including a source driver circuit that can be driven with a single power supply voltage can be provided. The power consumption of a device including a display device can be reduced. The structure of a display device, a driver circuit, or a device including a display device can be simplified.

According to one embodiment of the present invention, a semiconductor device capable of generating multi-tone image data can be provided. A display device including a source driver circuit with a small circuit area can be provided. A display device including a source driver circuit having low power consumption can be provided.

Note that the description of these effects does not preclude the existence of other effects. One embodiment of the present invention does not have to have all of these effects. Effects other than these can be derived from the description of the specification, the drawings, the claims, and the like.

### BRIEF DESCRIPTION OF THE DRAWINGS

FIG. 1A is a schematic view of an electronic device. FIG. 1B is a diagram illustrating the use state of the electronic device.

FIG. 2 is a flow chart illustrating a driving method example of an electronic device.

FIG. 3 is a block diagram showing a display device example.

FIG. 4A and FIG. 4B are circuit diagrams each showing a pixel example.

FIG. 5 is a circuit diagram showing a pixel example.

FIG. 6 is a timing chart illustrating a pixel operation example.

FIG. 7A to FIG. 7C are circuit diagrams each showing a pixel example.

FIG. 8A and FIG. 8B are circuit diagrams each showing a pixel example.

FIG. 9A and FIG. 9B are top views each showing a display device example.

FIG. 10A and FIG. 10B are perspective views showing a touch panel example.

FIG. 11 is a cross-sectional view showing a display device example.

FIG. 12 is a cross-sectional view showing a display device example.

FIG. 13 is a cross-sectional view showing a display device example.

FIG. 14A to FIG. 14D are cross-sectional views each showing a display device example. FIG. 14E to FIG. 14H are top views each showing a pixel example.

FIG. 15 is a diagram showing a structure example of a data processing device.

FIG. 16A and FIG. 16B are diagrams illustrating neural networks. FIG. 16C is a graph illustrating an output data example.

FIG. 17A1 to FIG. 17C2 are cross-sectional views each showing a transistor structure example.

FIG. 18A1 to FIG. 18C2 are cross-sectional views each showing a transistor structure example.

FIG. 19A is a table showing a classification of crystal structures of IGZO. FIG. 19B and FIG. 19C are graphs illustrating XRD spectra. FIG. 19D and FIG. 19E are views illustrating nanobeam electron diffraction patterns.

FIG. 20A to FIG. 20F are perspective views each showing an electronic device example.

FIG. 21A and FIG. 21B are perspective views each showing an electronic device example.

### MODE FOR CARRYING OUT THE INVENTION

Hereinafter, embodiments are described with reference to the drawings. Note that the embodiments can be implemented in many different modes, and it is readily understood by those skilled in the art that modes and details thereof can be changed in various ways without departing from the spirit and scope thereof. Thus, the present invention should not be construed as being limited to the following description of the embodiments.

Note that in the structures of the invention described below, the same portions or portions having similar functions are denoted by the same reference numerals in different drawings, and description thereof is not repeated. Furthermore, the same hatch pattern is used for the portions having similar functions, and the portions are not especially denoted by reference numerals in some cases.

Note that in each drawing described in this specification, the size, the layer thickness, or the region of each component is exaggerated for clarity in some cases. Therefore, they are not limited to the illustrated scale.

Note that in this specification and the like, the ordinal numbers such as “first” and “second” are used in order to avoid confusion among components and do not limit the number.

In this specification and the like, a display panel that is one embodiment of a display device has a function of displaying (outputting) an image or the like on (to) a display surface. Therefore, the display panel is one embodiment of an output device.

In this specification and the like, a substrate of a display panel to which a connector such as an FPC (Flexible Printed Circuit) or a TCP (Tape Carrier Package) is attached, or a substrate on which an IC is mounted by a COG (Chip On Glass) method or the like is referred to as a display panel module, a display module, or simply a display panel or the like in some cases.

### Embodiment 1

In this embodiment, an electronic device including a display device of one embodiment of the present invention, and a driving method example thereof will be described.

### [Structure Example of Electronic Device]

The electronic device of one embodiment of the present invention includes at least a display unit, an imaging unit, and an illuminance sensing unit. The electronic device of one embodiment of the present invention, which includes a variety of components and can drive the components in a complex manner, can also be referred to as a composite device or a composite system.

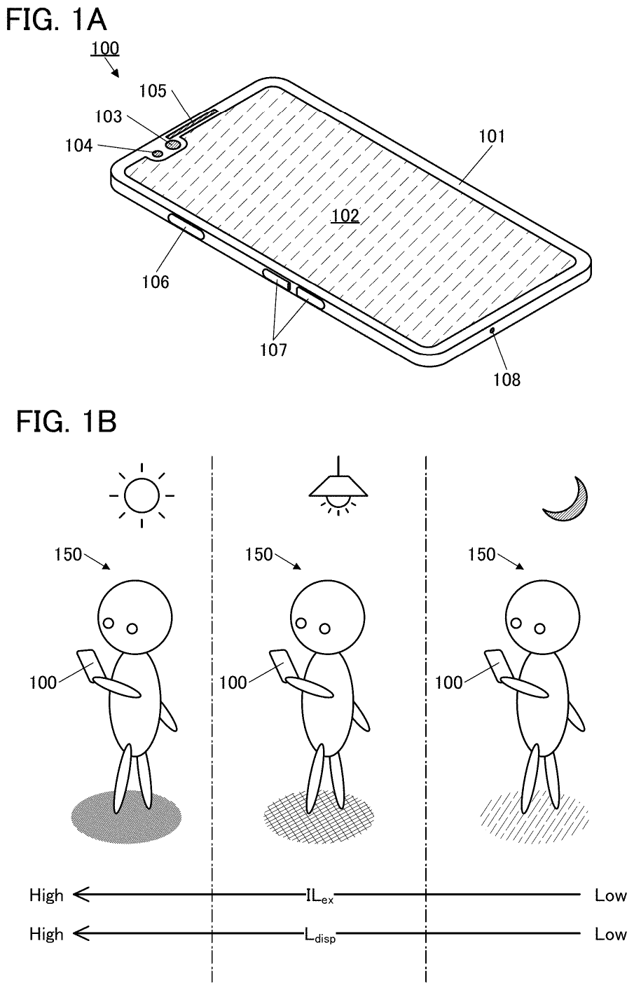

FIG. 1A is a schematic perspective view of an electronic device 100. The electronic device 100 includes a housing 101, a display unit 102, a camera 103, an illuminance sensor 104, a speaker 105, a power button 106, an operation button 107, a microphone 108, and the like. The electronic device 100 is an electronic device that can be used as, for example, a smartphone.

The camera 103 functions as the imaging unit. The illuminance sensor 104 functions as the illuminance sensing unit.

The display unit 102 includes a display device (a display panel). A specific structure of the display device will be described in detail in Embodiment 2.

The display device included in the display unit 102 includes a plurality of pixels, each of which is provided with at least one display element. The display device of one embodiment of the present invention has a function of retaining a first voltage based on a first pulse signal input from a source driver circuit, and a function of driving the display device with a third voltage that is obtained by adding the first voltage and a second voltage based on a second pulse signal. A signal based on image data can be used as the second pulse signal, and a signal based on a luminance correction value can be used as the first pulse signal. Thus, the display luminance of the display unit 102 can be changed in accordance with the correction value.

The display unit 102 may also have a function of a touch sensor. A variety of types such as a capacitive type, a resistive type, a surface acoustic wave type, an infrared type, an optical type, and a pressure-sensitive type can be used for the touch sensor. Alternatively, two or more of these types may be used in combination.

The display unit 102 may include a light-receiving element so as to have a function of capturing a fingerprint of a user's fingertip touching the display unit 102. This enables the electronic device 100 to execute fingerprint authentication with the display unit 102. As the light-receiving element, an inorganic photosensor using silicon or the like in an active layer, an organic photosensor using an organic compound in an active layer, or the like is preferably used. The display unit 102 can also function as a touch panel when sensing the position that a user's fingertip or the like touches.

The camera 103 is provided along a surface of the housing 101 on the side where the display unit 102 is provided. A user's face can be captured with the camera 103. From the captured image, the electronic device 100 can determine whether the user sees the display unit 102.

The illuminance sensor 104 is provided along a surface of the housing 101 on the side where the display unit 102 is provided. The illuminance sensor 104 can measure the illuminance of external light.

In the case where the display unit 102 includes a light-receiving element capable of receiving visible light, the illuminance of external light may be measured by the display unit 102. In that case, a structure without the illuminance sensor 104 may be employed or it is also possible to employ a structure where the illuminance of external light is measured by one or both of the illuminance sensor 104 and the display unit 102.

The power button 106 has a function of turning on or off the electronic device 100, a function of bringing the electronic device 100 into a sleep mode, a function of recovering the electronic device 100 from the sleep mode, and the like. A variety of functions such as volume control and luminance adjustment can be added to the operation button 107 in accordance with application software to be started.

In the electronic device 100 of one embodiment of the present invention, whether the user sees the display unit 102 can be determined by the camera 103. When the user sees the display unit 102, the illuminance of external light is measured by the illuminance sensor 104, and whether the display luminance of the display unit 102 is to be corrected and a correction value can be determined in accordance with the measured illuminance. The display unit 102 can perform display with an optimal luminance based on the correction value. Thus, display on the display unit 102 can be always performed with an optimal luminance without user's consciousness.

FIG. 1B shows the state where a user 150 uses the electronic device 100 under three environments. In FIG. 1B, an outdoor environment in sunny day, an indoor environment, and an outdoor environment at night are shown from the left.

The bottom of FIG. 1B shows the relationship between external illuminance ILₑₓ in each environment and display luminance L_{disp} of display on the electronic device 100. In FIG. 1B, the higher illuminance or luminance side is denoted by High whereas the lower illuminance or luminance side is denoted by Low.

In the outdoor environment in sunny day, the external illuminance ILₑₓ is extremely high and thus, the electronic device 100 determines the correction value so that the display luminance L_{disp} is high.

Meanwhile, in the outdoor environment at night, the external illuminance ILₑₓ is extremely low and thus, the electronic device 100 determines the correction value so that the display luminance L_{disp} is low.

The external illuminance ILₑₓ has an appropriate value in the indoor environment in many cases. Thus, display can be performed without correction in the caser where, for example, a predetermined display luminance L_{disp} is an optimal luminance.

### [Driving Method Example of Electronic Device]

A more specific example of a driving method of the electronic device will be described below with reference to a flow chart.

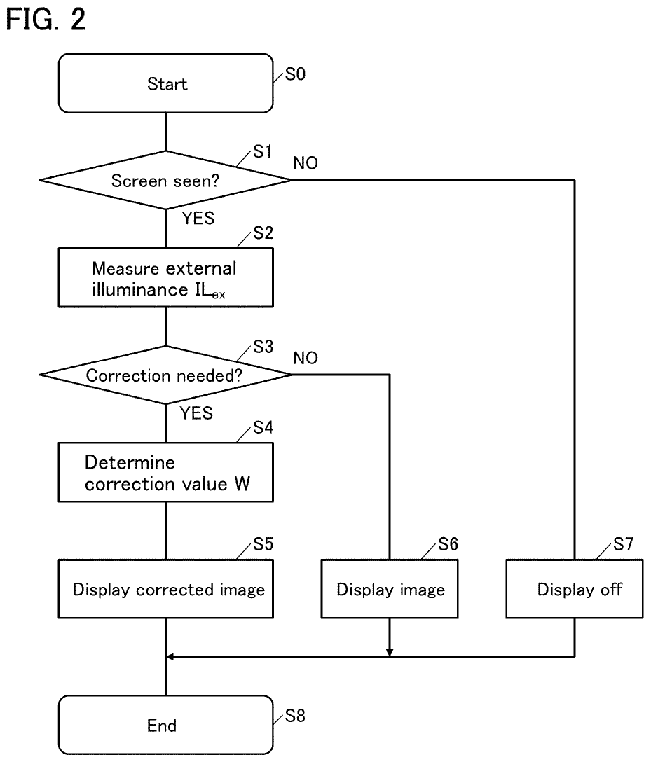

FIG. 2 is a flow chart regarding a driving method of the electronic device 100. The flow chart shown in FIG. 2 includes Step S0 to Step S8. Each step is described below.

In Step S0, the operation starts.

In Step S1, the electronic device 100 determines whether the user sees a screen (the display unit 102). In the case where the user is determined to see the screen (YES) in Step S1, the process proceeds to Step S2. In the case where the user is determined not to see the screen (NO), the process proceeds to Step S7.

In Step S1, the user can be determined to see the screen in the case where the user's face is displayed in an image captured by the camera 103. For example, more accurate determination is possible when it is determined that the user sees the screen by sensing the user's eyes and nose.

In Step S2, the external illuminance ILₑₓ is measured. The measurement is performed by the illuminance sensor 104. Alternatively, the measurement is performed by one or both of the illuminance sensor 104 and the display unit 102.

In Step S3, the electronic device 100 determines the necessity of correction from the measured value of the external illuminance ILₑₓ. In the case where the correction is determined to be necessary, the process proceeds to Step S4. In the case where the correction is determined to be unnecessary, the process proceeds to Step S6.

In Step S4, the electronic device 100 determines a correction value W in accordance with the value of the external illuminance ILₑₓ. For example, in the case where the external illuminance ILₑₓ has a value higher than a predetermined range, the correction value W is determined so as to increase the display luminance L_{disp}. Meanwhile, in the case where the external illuminance ILₑₓ has a value lower than the predetermined range, the correction value W is determined so as to decrease the display luminance L_{disp}.

For example, the correction value W can be determined with reference to a data table that specifies the relationship between the value of the external illuminance ILₑₓ and the correction value W. The correction value W is preferably determined in accordance with image data to be displayed. The correction value W can differ, for example, between the case where a bright image is displayed and the case where a dark image is displayed. A different correction value W may be used in each pixel or each area of the display unit 102.

In Step S5, a corrected image is displayed on the display unit 102.

More specifically, a corrected image is displayed using the first pulse signal based on the correction value W and the second pulse signal based on image data, which are output from a source driver included in the display device provided in the display unit 102.

In Step S6, an image based on the image data is displayed.

In Step S6, an image based on the input image data can be displayed with a predetermined luminance without correction of luminance. Here, the predetermined luminance can be a luminance that is determined in advance by a manufacturer or the like at the time of shipping of the electronic device 100 or a luminance that is determined by the user.

In Step S7, display is turned off.

Since the user does not see the screen in Step S7, the power consumption of the electronic device 100 can be reduced by turning off the display.

In Step S8, the operation ends.

Note that the process may proceed to Step S2 after Step S8. This enables the electronic device 100 to always perform display with an optimal luminance.

The process may proceed to Step S1 after Step S8. This allows sensing of the user's eyes taken off from the screen and turning off of the display, resulting in a reduction in power consumption. The display of images can be started when the user sees the screen again, whereby the power consumption can be reduced while the user is free from stress.

The above is the description of the driving method example of the electronic device.

At least part of this embodiment can be implemented in combination with the other embodiments described in this specification as appropriate.

### Embodiment 2

In this embodiment, a semiconductor device of one embodiment of the present invention and a display device including the semiconductor device will be described.

### <Circuit Configuration for Display Device>

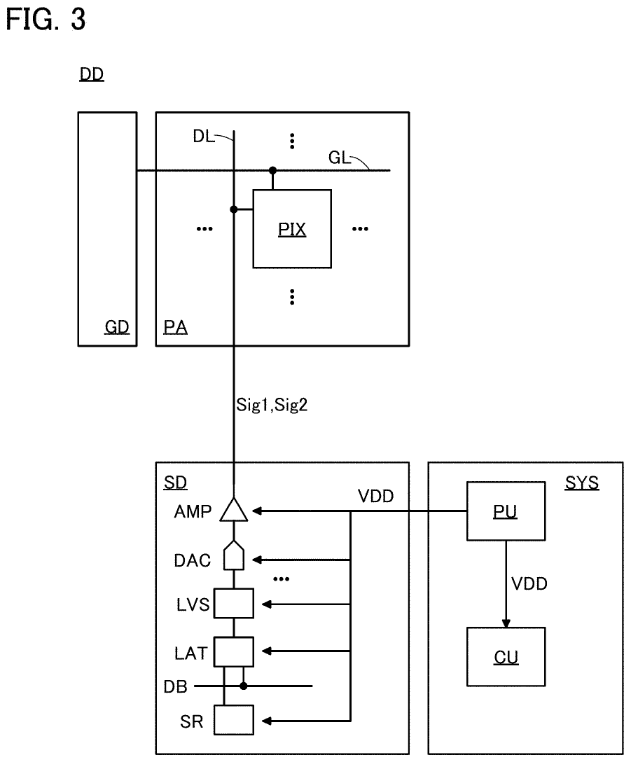

First, a structure example of a display device is described. FIG. 3 is a block diagram showing a display device example. A display device DD includes a display unit PA, a source driver circuit SD, and a gate driver circuit GD.

The display unit PA includes a plurality of pixels PIX. In FIG. 3, only one of the plurality of pixels PIX in the display unit PA is shown and the other pixels PIX are omitted. The plurality of pixels PIX in the display unit PA are preferably arranged in a matrix.

In FIG. 3, the pixel PIX is electrically connected to the source driver circuit SD through a wiring DL. In addition, the pixel PIX is electrically connected to the gate driver circuit GD through a wiring GL. Since the display unit PA includes the plurality of pixels PIX, more than one pixel PIX may be electrically connected to the wiring DL. Similarly, more than one pixel PIX may be electrically connected to the wiring GL. Furthermore, more than one wiring DL and more than one wiring GL may be provided in accordance with the number of the pixels PIX included in the display unit PA. Depending on the circuit configuration of the pixel PIX, more than one wiring DL or more than one wiring GL may be electrically connected to one pixel PIX.

The pixel PIX can include one or more subpixels. The pixel PIX can have, for example, a structure with one subpixel (any one color of red (R), green (G), blue (B), white (W), and the like), a structure with three subpixels (e.g., three colors of red (R), green (G), and blue (B)), or a structure with four or more subpixels (e.g., four colors of red (R), green (G), blue (B), and white (W), or four colors of red (R), green (G), blue (B), and yellow (Y)). Note that color elements used for the subpixels are not limited to the above, and may be combined with cyan (C), magenta (M), or the like as necessary.

The pixel PIX includes at least one or more display elements. A variety of display elements such as a light-emitting element, a liquid crystal element, a microcapsule, an electrophoretic element, an electrowetting element, an electrofluidic element, an electrochromic element, and a MEMS element can be used as the display element.

As the light-emitting element, an organic EL (Electro Luminescence) element, an LED (Light Emitting Diode) element, an inorganic EL element, or the like can be used.

Examples of the LED element include a macro LED (also referred to as a huge LED), a mini LED, a micro LED, and the like in descending order in size. Here, an LED chip whose one side size is larger than 1 mm is called a macro LED, an LED chip whose one side size is larger than 100 μm and smaller than or equal to 1 mm is called a mini LED, and an LED chip whose one side size is smaller than or equal to 100 μm is called a micro LED. It is particularly preferable to use a mini LED or a micro LED as an LED element applied to the pixel PIX. The use of a micro LED can achieve an extremely high-definition display device.

The source driver circuit SD has a function of generating image data to be input to the pixel PIX included in the display unit PA and a function of transmitting the image data to the pixel PIX.

The source driver circuit SD can include, for example, a shift register SR, a latch circuit LAT, a level shifter circuit LVS, a digital-analog converter circuit DAC, an amplifier circuit AMP, and a data bus wiring DB. In FIG. 3, an output terminal of the shift register SR is electrically connected to a clock input terminal of the latch circuit LAT; an input terminal of the latch circuit LAT is electrically connected to the data bus wiring DB; an output terminal of the latch circuit LAT is electrically connected to an input terminal of the level shifter circuit LVS; an output terminal of the level shifter circuit LVS is electrically connected to an input terminal of the digital-analog converter circuit DAC; an output terminal of the digital-analog converter circuit DAC is electrically connected to an input terminal of the amplifier circuit AMP; and an output terminal of the amplifier circuit AMP is electrically connected to the display unit PA.

Note that the latch circuit LAT, the level shifter circuit LVS, the digital-analog converter circuit DAC, and the amplifier circuit AMP that are shown in FIG. 3 are provided for one wiring DL. That is, the numbers of the latch circuits LAT, the level shifter circuits LVS, the digital-analog converter circuits DAC, and the amplifier circuits AMP each need to be more than one, depending on the number of the wirings SL. In this case, the shift register SR is configured to sequentially transmit pulse signals to the clock input terminals of the plurality of latch circuits LAT.

The data bus wiring DB is a wiring for transmitting a digital signal containing image data to be input to the display unit PA. The image data has gray levels; as the number of gray levels increases, variations in color or brightness can be expressed with a more smooth gradation and a more natural image can be displayed on the display unit PA. Note that an increase in the number of gray levels increases the volume of the image data and requires a digital-analog converter circuit with high resolving power.

A digital signal containing image data is input from the data bus wiring DB to the input terminal of the latch circuit LAT. Then, in response to a signal transmitted from the shift register SR, the latch circuit LAT retains the image data or outputs the retained image data from the output terminal.

The level shifter circuit LVS has a function of converting an input signal into an output signal with a higher amplitude voltage or a lower amplitude voltage. In FIG. 3, the level shifter circuit LVS has a function of converting the amplitude voltage of a digital signal containing image data that is transmitted from the latch circuit LAT into an amplitude voltage at which the digital-analog converter circuit DAC properly operates.

The digital-analog converter circuit DAC has a function of converting an input digital signal containing image data into an analog signal and a function of outputting the analog signal from the output terminal. In particular, in the case where multi-tone image data is displayed on the display unit PA, the digital-analog converter circuit DAC needs to be a high-resolving-power digital-analog converter circuit.

The amplifier circuit AMP has a function of amplifying an analog signal input through the input terminal and outputting the analog signal from the output terminal. The amplifier circuit AMP is provided between the digital-analog converter circuit DAC and the display unit PA; thus, image data can be stably transmitted to the display unit PA. A voltage follower circuit including an operational amplifier and the like can be used as the amplifier circuit AMP. Note that in the case where a circuit including a differential input circuit is used as an amplifier circuit, the offset voltage of the differential input circuit is preferably set as close to 0 V as possible.

Through the above operations, the source driver circuit SD can convert the digital signal containing image data that has been transmitted from the data bus wiring DB into an analog signal and transmit the analog signal to the display unit PA. The source driver circuit SD has a function of generating a first signal Sig1 and a second signal Sig2 that are analog signals and supplying the first signal Sig1 and the second signal Sig2 to the pixel PIX through the wiring DL. Here, the first signal Sig1 and the second signal Sig2 are pulse signals each having an amplitude corresponding to image data.

The gate driver circuit GD has a function of selecting a pixel PIX to which image data is input among the plurality of pixels PIX included in the display unit PA.

Image data can be input to the display unit PA in the following manner, for example: the gate driver circuit GD transmits a selection signal to the plurality of pixels PIX electrically connected to one wiring GL so that image data write switching elements in the plurality of pixels PIX are turned on, and then, image data is transmitted from the source driver circuit SD to the plurality of pixels PIX through the wirings DL to be written.

One embodiment of the present invention is not limited to the structure of the display device DD shown in FIG. 3. In one embodiment of the present invention, a component of the display device DD can be changed as appropriate according to the circumstances such as the design specifications and the purpose, for example.

In the case where a multi-tone image is displayed on the display unit PA, the digital-analog converter circuit DAC needs to have high resolving power. In that case, the size of the digital-analog converter circuit DAC increases; thus, the circuit area of the source driver circuit SD increases in some cases. When circuit elements such as a transistor and a capacitor in a circuit included in the source driver circuit SD are shrunk to reduce the circuit area of the source driver circuit SD, the electrical characteristics of the circuit elements might degrade through the influence of parasitic resistance, the influence of a structure variation caused in manufacture of the circuit elements, or the like.

In view of the above, one embodiment of the present invention is constructed such that the potential of an image data retention unit of the pixel PIX is changed to a potential with higher resolving power than that of the digital-analog converter circuit DAC through capacitive coupling. This eliminates the necessity of increasing the resolving power of the digital-analog converter circuit, so that the digital-analog converter circuit with low resolving power can be used. Consequently, the circuit area of the source driver circuit SD including the digital-analog converter circuit DAC can be reduced, and the power consumption of the source driver circuit SD can be reduced.

FIG. 3 shows an example in which the display device DD includes a system circuit SYS. The system circuit SYS has a function of controlling the operation of the source driver circuit SD. For example, the system circuit SYS has a function of supplying a variety of signals such as a data signal, a clock signal, and a start pulse signal and a power supply voltage to the source driver circuit SD.

Shown here is an example in which the system circuit SYS is provided with a power supply generation unit PU and a control unit CU.

The control unit CU includes at least a logic circuit. For example, the control unit CU can have a structure that includes a processor such as a CPU (Central Processing Unit) or a GPU (Graphics Processing Unit).

The power supply generation unit PU has a function of generating a power supply voltage VDD to be supplied to the control unit CU and the source driver circuit SD. For example, the power supply generation unit PU can convert power supplied from a battery, a power supply plug, or the like to generate the power supply voltage VDD.

As described later, the pixel PIX included in the display device DD can generate a voltage obtained by adding the amplitudes of two signals (the first signal Sig1 and the second signal Sig2) to drive the display element. Thus, when display is performed on the pixel PIX at the highest gray level, the voltage of each of the first signal Sig1 and the second signal Sig2 that are supplied from the source driver circuit SD can be a half of the sum of the voltages of these signals or a voltage in the vicinity thereof.

Thus, the source driver circuit SD does not need a high power supply voltage for generating an analog signal and can operate with the single power supply voltage VDD. In FIG. 3, the power supply voltage VDD supplied from the system circuit SYS to the source driver circuit SD and the power supply voltage VDD for driving the control unit CU can be common. The power supply voltage VDD supplied from the system circuit SYS is supplied to the shift register SR, the latch circuit LAT, the level shift circuit LVS, the digital-analog converter circuit DAC, and the amplifier circuit AMP in the source driver circuit SD. Note that in that case, it is also possible to omit the level shift circuit LVS.

Such a configuration eliminates the need for a booster circuit for boosting a power supply voltage, such as a DCDC converter, between the system circuit SYS and the source driver circuit SD. That is, the power supply voltage VDD supplied from the system circuit SYS to the source driver circuit SD is directly supplied to the source driver circuit SD without being boosted and is used to generate the first signal Sig1 and the second signal Sig2.

In addition, it is not necessary to provide a booster circuit for boosting the power supply voltage VDD in the source driver circuit SD; thus, the circuit configuration of the source driver circuit SD can be simplified and the power consumption of the source driver circuit SD can be reduced. In other words, the source driver circuit SD can generate the first signal Sig1 and the second signal Sig2 without boosting the power supply voltage VDD.

For example, when one of the drive voltages of respective circuits including the control unit CU in the system circuit SYS is 1.8 V, 2.5 V, 3.3 V, or a voltage in the vicinity thereof, the voltage can be supplied to the source driver circuit SD as the power supply voltage VDD. Accordingly, the power supply generation unit PU in the system circuit SYS does not need to generate a high power supply voltage to be supplied to the source driver circuit SD, and the circuit configuration of the power supply generation unit PU can be simplified.

With such a configuration, the source driver circuit SD can be driven at a low voltage; thus, the power consumption of the source driver circuit SD and the display device DD can be drastically reduced.

Note that in this specification and the like, in the case where a voltage is referred to as a voltage in the vicinity of a certain voltage, the voltage includes the range of ±20% of the voltage.

### <Pixel Circuit Configuration>

A circuit configuration example of the pixel PIX that is a semiconductor device of one embodiment of the present invention will be described.

The pixel PIX shown below has a function of retaining a first voltage corresponding to a first pulse signal (the first signal Sig1) input from the source driver circuit SD and a function of driving a display element with a third voltage obtained by adding the first voltage and a second voltage corresponding to a second pulse signal (the second signal Sig2). That is, in the pixel PIX, the display element can be driven with a voltage higher than the maximum voltage of each of the first pulse signal and the second pulse signal input from the source driver circuit SD.

For example, in the case where a light-emitting element is used as the display element, an image can be displayed when the light-emitting element emits light with a luminance based on the third voltage. In the case where a liquid crystal element is used as the display element, the alignment of the liquid crystal is changed with the third voltage to change the transmittance of light from a light source such as a backlight, so that an image can be displayed.

The power supply voltage VDD that is used by the source driver circuit SD shown in FIG. 3 to generate the first signal Sig1 and the second signal Sig2 can be a voltage lower than the maximum value of the third voltage that can be generated in the pixel PIX (for example, the value of the third voltage when display is performed at the highest gray level). The power supply voltage VDD can be suitably a half (½) of the maximum value of the third voltage or a voltage in the vicinity thereof.

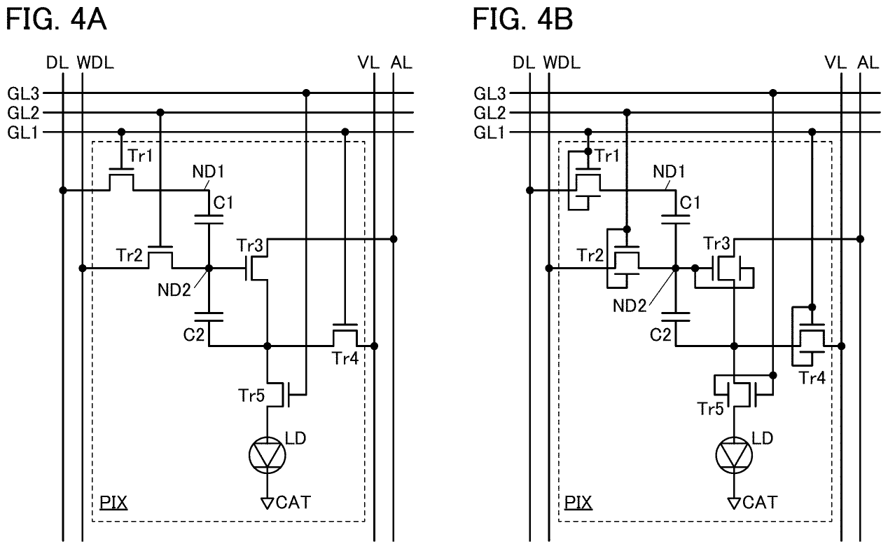

The pixel PIX shown in FIG. 4A is an example in which a light-emitting element is used as the display element.

The pixel PIX shown in FIG. 4A includes a transistor Tr1 to a transistor Tr5, a capacitor C1, a capacitor C2, and a light-emitting element LD. In addition, the wiring DL, a wiring WDL, a wiring GL1 to a wiring GL3, a wiring VL, a wiring AL, and a wiring CAT are electrically connected to the pixel PIX.

The transistor Tr1, the transistor Tr2, the transistor Tr4, and the transistor Tr5 each function as a switching element. The transistor Tr3 functions as a driving transistor that controls a current flowing to the light-emitting element LD. In addition, structures described in Embodiment 3 can be applied to the transistor Tr1 to the transistor Tr5.

Each of the wiring DL and the wiring WDL is a wiring for transmitting image data to the pixel PIX and corresponds to the wiring DL of the display device DD in FIG. 3. Each of the wiring GL1 to the wiring GL3 is a selection signal line for the pixel PIX and is a wiring corresponding to the wiring GL of the display device DD in FIG. 3.

The wiring VL is a wiring for applying a predetermined potential to a specific node in the pixel PIX. The wiring AL is a wiring for supplying a current flowing to the light-emitting element LD.

The wiring CAT is a wiring for applying a predetermined potential to an output terminal of the light-emitting element LD. The predetermined potential can be, for example, a reference potential, a low-level potential, or a potential lower than these potentials.

A first terminal of the transistor Tr1 is electrically connected to a first terminal of the capacitor C1; a second terminal of the transistor Tr1 is electrically connected to the wiring DL; and a gate of the transistor Tr1 is electrically connected to the wiring GL1. A first terminal of the transistor Tr2 is electrically connected to a gate of the transistor Tr3, a second terminal of the capacitor C1, and a first terminal of the capacitor C2; a second terminal of the transistor Tr2 is electrically connected to the wiring WDL; and a gate of the transistor Tr2 is electrically connected to the wiring GL2.

Note that in this embodiment, an electrical connection point of the first terminal of the transistor Tr1 and the first terminal of the capacitor C1 is referred to as a node ND1, and an electrical connection point of the first terminal of the transistor Tr2, the gate of the transistor Tr3, the second terminal of the capacitor C1, and the first terminal of the capacitor C2 is referred to as a node ND2.

Here, a voltage (potential) written to the node ND2 from the wiring WDL through the transistor Tr2 corresponds to the first voltage (potential). In addition, a voltage written to the node ND1 from the wiring DL through the transistor Tr1 corresponds to the second voltage. Furthermore, when the second voltage is written to the node ND1, the second voltage is added to the first voltage by capacitive coupling through the capacitor C1, so that the voltage of the node ND2 is changed. The resulting voltage of the node ND2 corresponds to the third voltage.

A first terminal of the transistor Tr3 is electrically connected to the wiring AL, and a second terminal of the transistor Tr3 is electrically connected to a first terminal of the transistor Tr4, a first terminal of the transistor Tr5, and a second terminal of the capacitor C2. A second terminal of the transistor Tr4 is electrically connected to the wiring VL, and a gate of the transistor Tr4 is electrically connected to the wiring GL1. A second terminal of the transistor Tr5 is electrically connected to an input terminal of the light-emitting element LD, and a gate of the transistor Tr5 is electrically connected to the wiring GL3. The output terminal of the light-emitting element LD is electrically connected to the wiring CAT.

In the pixel PIX in FIG. 4A, each of the transistor Tr1, the transistor Tr2, and the transistor Tr5 is preferably an OS transistor. In particular, an OS transistor is preferably an oxide containing at least one of indium, an element M (the element M is aluminum, gallium, yttrium, or tin), and zinc in a channel formation region. The oxide will be described in detail in Embodiment 4. The application of such OS transistors to the transistor Tr1, the transistor Tr2, and the transistor Tr5 enables the off-state currents of the transistors to be extremely low. In the case where data is retained in the first terminal of the capacitor C1 (the node ND1), when the transistor Tr1 is an OS transistor, data retained in the node ND1 can be prevented from being corrupted by the off-state current. Similarly, when data is retained in the gate of the transistor Tr3, the second terminal of the capacitor C1, and the first terminal of the capacitor C2 (the node ND2), the use of an OS transistor as the transistor Tr2 can prevent data retained in the node ND2 from being corrupted by the off-state current. Furthermore, in the case where light emission of the light-emitting element LD is temporarily stopped, the use of an OS transistor as the transistor Tr5 can prevent light emission of the light-emitting element LD due to the off-state current.

For example, a transistor including silicon in a channel formation region (hereinafter referred to as a Si transistor) can be applied to each of the transistor Tr3 and the transistor Tr4. Hydrogenated amorphous silicon, microcrystalline silicon, or polycrystalline silicon can be used as silicon, for example.

An OS transistor can be applied to each of the transistor Tr3 and the transistor Tr4. In particular, when all of the transistor Tr1 to the transistor Tr5 are OS transistors, the transistors can be formed at the same time, allowing shortening of manufacturing steps of the display unit PA in some cases. Thus, the time needed to produce the display unit PA can be shortened, increasing the number of the display units PA produced in a certain period.

### <<Operation Example>>

Next, an operation example of the pixel PIX shown in FIG. 4A is described. Note that the wiring DL and the wiring WDL of the pixel PIX in FIG. 4A are assumed to be electrically connected to the source driver circuit SD in FIG. 3 so that image data can be transmitted to the pixel PIX.

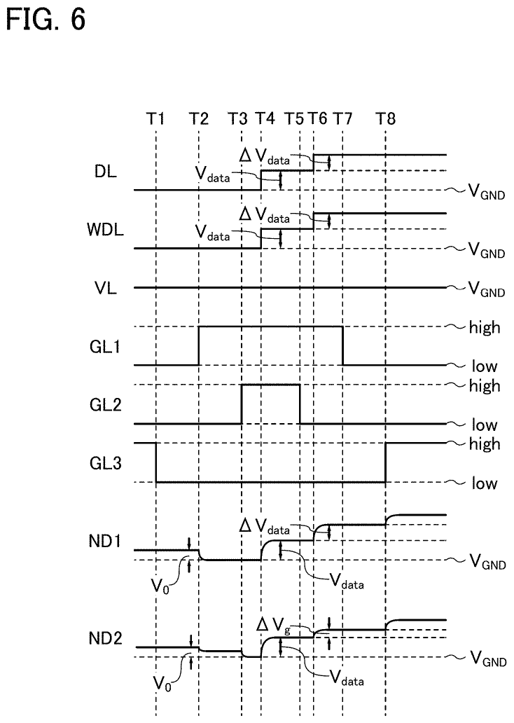

FIG. 6 is a timing chart showing an operation example of the pixel PIX shown in FIG. 4A. The timing chart shown in FIG. 6 shows changes in the potentials of the wiring DL, the wiring WDL, the wiring VL, the wiring GL1 to the wiring GL3, the node ND1, and the node ND2 in a period from Time T1 to Time T8 and at time close to the period. Note that “high” described in FIG. 6 indicates a high-level potential, and “low” indicates a low-level potential. In addition, V_{GND} described in FIG. 6 indicates a reference potential.

Note that V_{GND} is assumed to be constantly applied to the wiring VL during the period from Time T1 to Time T8 and at the time close to the period.

Note that in this operation example, the transistor Tr1, the transistor Tr2, the transistor Tr4, and the transistor Tr5 are assumed to operate in a linear region unless otherwise specified. In other words, the gate voltage, source voltage, and drain voltage of each of the transistor Tr1, the transistor Tr2, the transistor Tr4, and the transistor Tr5 are assumed to be appropriately biased to voltages in the range where the transistor operates in the linear region.

Furthermore, in this operation example, the transistor Tr3 is assumed to operate in a saturation region unless otherwise specified. In other words, the gate voltage, source voltage, and drain voltage of the transistor Tr3 are assumed to be appropriately biased to voltages in the range where the transistor operates in the saturation region. Note that even when the operation of the transistor Tr3 deviates from operation in an ideal saturation region, the gate voltage, source voltage, and drain voltage of the transistor Tr3 are regarded as being appropriately biased as long as the accuracy of an output current is within a desired range.

### [Before Time T1]

Before Time T1, a low-level potential is applied to the wiring GL1 and the wiring GL2, and a high-level potential is applied to the wiring GL3. When the potential of the wiring GL1 is a low-level potential, a low-level potential is applied to the gates of the transistor Tr1 and the transistor Tr4; thus, the transistor Tr1 and the transistor Tr4 are set in off states. That is, the wiring DL and the node ND1 are electrically disconnected. Similarly, when the potential of the wiring GL2 is a low-level potential, a low-level potential is applied to the gate of the transistor Tr2; thus, the transistor Tr2 is set in an off state. That is, the wiring WDL and the node ND2 are electrically disconnected. When the potential of the wiring GL3 is a high-level potential, a high-level potential is applied to the gate of the transistor Tr5; thus, the transistor Tr5 is set in an on state. That is, the input terminal of the light-emitting element LD and the first terminal of the transistor Tr5 are electrically connected.

When a difference between the potential of the node ND2 and the potential of a source of the transistor Tr3 (gate-source voltage) is greater than the threshold voltage of the transistor Tr3, the transistor Tr3 is set in an on state, and a current flowing between the source and a drain of the transistor Tr3 is determined in accordance with the gate-source voltage of the transistor Tr3. In the case where the second terminal of the transistor Tr3 is the source at this time, the current flows from the wiring AL to the input terminal of the light-emitting element LD through the transistor Tr3 and the transistor Tr5. Consequently, the light-emitting element LD emits light. Note that in the timing chart shown in FIG. 6, the potential of the node ND2 at which the transistor Tr3 is set in an off state is denoted as Vo (that is, a difference between Vo and the source potential of the transistor Tr3 is less than the threshold voltage of the transistor Tr3; thus, the light-emitting element LD does not emit light).

In order to briefly describe this operation example, the potential of the node ND1 before Time T1 is also set to Vo.

Assume that before Time T1, image data is not transmitted from the source driver circuit SD to the pixel PIX and V_{GND} is applied to the wiring DL and the wiring WDL.

### [Time T1]

At Time T1, a low-level potential is applied to the wiring GL3. Thus, in a period from Time T1 to Time T2, a low-level potential is applied to the gate of the transistor Tr5, so that the transistor Tr5 is set in an off state. Consequently, a current does not flow to the input terminal of the light-emitting element LD regardless of whether the transistor Tr3 is in an on state or an off state, so that the light-emitting element LD does not emit light.

### [Time T2]

At Time T2, a high-level potential is applied to the wiring GL1. Thus, in a period from Time T2 to Time T3, a high-level potential is applied to the gate of each of the transistor Tr1 and the transistor Tr4, so that the transistor Tr1 and the transistor Tr4 are set in on states.

When the transistor Tr1 is set in an on state, the wiring DL and the node ND1 are electrically connected. Thus, the potential of the node ND1 becomes V_{GND}. When the transistor Tr4 is set in an on state, the wiring VL and the second terminal of the capacitor C2 are electrically connected. Thus, the potential of the second terminal of the capacitor C2 becomes V_{GND}.

Since the second terminal of the capacitor C1 (the node ND2) is in a floating state, when the potential of the node ND1 changes, the potential of the node ND2 also changes due to capacitive coupling. Note that the amount of change in the potential of the node ND2 depends on the amount of change in the potential of the node ND1, the capacitance of the capacitor C1, and the like. In this operation example, the potential of the node ND1 decreases from Vo to V_{GND}; accordingly, the potential of the node ND2 decreases from Vo.

### [Time T3]

At Time T3, a high-level potential is applied to the wiring GL2. Thus, in a period from Time T3 to Time T4, a high-level potential is applied to the gate of the transistor Tr2, so that the transistor Tr2 is set in an on state.

When the transistor Tr2 is set in an on state, the wiring WDL and the node ND2 are electrically connected. Thus, the potential of the node ND2 becomes V_{GND}. Note that since the transistor Tr1 is in an on state, the potential of the node ND1 is not changed by a change in the potential of the node ND2. Similarly, since the transistor Tr4 is in an on state, the potential of the second terminal of the capacitor C2 is also not changed by a change in the potential of the node ND2.

### [Time T4]

At Time T4, an analog signal is transmitted as image data from the source driver circuit SD to the wiring DL and the wiring WDL. Here, V_{data} is input as the potential of the analog signal to the wiring DL and the wiring WDL.

Since the transistor Tr1 is in an on state, V_{data} is applied from the wiring DL to the first terminal of the capacitor C1 (the node ND1). In addition, the transistor Tr2 is also in an on state; thus, V_{data} is applied from the wiring WDL to the gate of the transistor Tr3, the second terminal of the capacitor C1, and the first terminal of the capacitor C2 (the node ND2). Note that the potential of the second terminal of the capacitor C2 is not changed by changes in the potentials of the node ND1 and the node ND2 because the transistor Tr4 is in an on state.

### [Time T5]

At Time T5, a low-level potential is applied to the wiring GL2. Thus, in a period from Time T5 to Time T6, a low-level potential is applied to the gate of the transistor Tr2, so that the transistor Tr2 is set in an off state.

When the transistor Tr2 is set in an off state, the wiring WDL and the node ND2 are electrically disconnected. Thus, the node ND2 is brought into a floating state.

### [Time T6]

At Time T6, a signal that is obtained by adding the potential of A V_{data} to the potential V_{data} input in a period from Time T4 to Time T5 is transmitted from the source driver circuit SD to the wiring DL and the wiring WDL. That is, the potentials of the wiring DL and the wiring WDL are V_{data}+A.

Since the transistor Tr1 is in an on state, V_{data}+ΔV_{data} is applied from the wiring DL to the node ND1. That is, the potential of the node ND1 changes from V_{data} in the period from Time T4 to Time T6 to V_{data}+ΔV_{data}.

Since the transistor Tr2 is in an off state, V_{data}+ΔV_{data} is not applied from the wiring WDL to the node ND2. However, the potential of the node ND1 changes from V_{data} to V_{data}+ΔV_{data} and the node ND2 is in a floating state; thus, the change in the potential of the node ND1 causes a change in the potential of the node ND2 due to the capacitive coupling of the capacitor C1. In the timing chart of FIG. 6, the amount of change in the potential of the node ND2 is denoted as ΔV_{g}, and ΔV_{g} can be estimated by Equation (E1) below.

$$\begin{matrix}[ Equation 1 ] & \\ {Δ V}_{g} = \frac{{C}_{1}}{{C}_{1} + {C}_{2}} Δ {V}_{data} & ( E1 )\end{matrix}$$

Therefore, when the potential of the node ND2 is V_{ND2}, the capacitance of the capacitor C1 is C₁, and the capacitance of the capacitor C2 is C₂, V_{ND2} can be expressed by Equation (E2) below.

$$\begin{matrix}[ Equation 2 ] & \\ {V}_{ND 2} = {V}_{data} + \frac{{C}_{1}}{{C}_{1} + {C}_{2}} {Δ V}_{data} & ( E2 )\end{matrix}$$

Note that although the potential of the wiring WDL is V_{data}+ΔV_{data} at Time T6, V_{data}+ΔV_{data}, the potential of the wiring WDL, is not input to any element in the circuit configuration example shown in FIG. 4A. For this reason, in the circuit configuration example shown in FIG. 4A, the potential of the wiring WDL does not have to be V_{data}+ΔV_{data} at Time T6.

### [Time T7]

At Time T7, a low-level potential is applied to the wiring GL1. Thus, in a period from Time T7 to Time T8, a low-level potential is applied to the gate of the transistor Tr1, so that the transistor Tr1 is set in an off state. Consequently, the node ND1 is brought into a floating state, and the potential of the node ND1 is retained by the capacitor C1.

In the period from Time T7 to Time T8, a low-level potential is applied to the gate of the transistor Tr4, so that the transistor Tr4 is set in an off state. At this time, the potential of the second terminal of the capacitor C2 is V_{GND} and the potential of the gate of the transistor Tr3 (the node ND2) is V_{ND2}; thus, in the case where V_{ND2}−V_{GND} is higher than the threshold voltage, the transistor Tr3 is set in an on state. Furthermore, the current flowing between the source and the drain of the transistor Tr3 is determined in accordance with V_{ND2}−V_{GND}.

### [Time T8]

At Time T8, a high-level potential is applied to the wiring GL3. Thus, after Time T8, a high-level potential is applied to the gate of the transistor Tr5, so that the transistor Tr5 is set in an on state. Accordingly, a current flowing from the wiring AL is input to the input terminal of the light-emitting element LD through the transistor Tr3 and the transistor Tr5, so that the light-emitting element LD emits light. At this time, a voltage is applied between the input terminal and the output terminal of the light-emitting element LD and a predetermined potential is applied to the wiring CAT, so that the potential of an electrical connection point of the second terminal of the transistor Tr3, the first terminal of the transistor Tr4, the first terminal of the transistor Tr5, and the second terminal of the capacitor C2 increases. Since the node ND1 and the node ND2 are each in a floating state, when the potential of the electrical connection point increases, the potentials of the node ND1 and the node ND2 also increase due to capacitive coupling in some cases. In the timing chart of FIG. 6, the potentials of the node ND1 and the node ND2 after Time T8 are higher than the potentials of the node ND1 and the node ND2 in the period from Time T7 to Time T8.

Note that the luminance of the light-emitting element LD is determined by the current flowing to the light-emitting element LD. According to Kirchhoff s law, the current flowing to the light-emitting element LD is substantially equal to the current flowing between the source and the drain of the transistor Tr3; thus, the luminance of the light-emitting element LD is determined by the gate-source voltage of the transistor Tr3.

As described above, the operations in the period from Time T1 to Time T8 and at the time close to the period in the timing chart of FIG. 6 are performed on the pixel PIX shown in FIG. 4A, so that a potential with higher resolving power than that of the digital-analog converter circuit DAC can be applied to the image data retention portion (the node ND2) of the pixel PIX.

### <<Specific Example>>

Described here is an example of displaying multi-tone image data compared to image data output from the digital-analog converter circuit DAC on the display unit PA of the display device DD according to the operation example described above.

In this example, a 6-bit digital-analog converter circuit is provided as the digital-analog converter circuit DAC of the source driver circuit SD, and the capacitance ratio of the capacitor C1 to the capacitor C2 included in the pixel PIX is set to C₁:C₂=1:15.

By using a 6-bit digital-analog converter circuit DAC as the digital-analog converter circuit DAC, V_{data} that is written to the node ND1 and the node ND2 of the pixel PIX can have a value ranging from “000000” to “111111” in binary notation. Here, when the voltage value of “111111” is 6.3 V, the voltage value possible for V_{data} that can be output from the digital-analog converter circuit DAC is in the range of 0 V to 6.3 V in 0.1 V steps.

Thus, in the operation example described above, V_{data} in the range of 0 V to 6.3 V can be written to the node ND1 and the node ND2 of the pixel PIX in the period from Time T4 to Time T5.

[The Case where V_{data} has a Value in the Range of 0 V to 4.8 V]

First, the case is described in which V_{data} in the range of 0 V to 4.8 V (in the range of “000000” to “110000” in binary notation) is written to the node ND1 and the node ND2 of the pixel PIX.

Since the capacitance ratio of the capacitor C1 to the capacitor C2 is C₁:C₂=1:15, Equation (E1) is represented by Equation (E3) below.

$$\begin{matrix}[ Equation 3 ] & \\ Δ {V}_{g} = \frac{1}{16} Δ {V}_{data} = \frac{1}{{2}^{4}} {Δ V}_{data} & ( E3 )\end{matrix}$$

Here, ΔV_{data} is assumed to be able to have a value ranging from “000000” to “001111” in binary notation, for example. In this case, a voltage value that ΔV_{data} can have is in the range of 0 V to 1.5 V in 0.1 V steps. That is, from Equation (E3), ΔV_{g} can have a value ranging from 0 V to 0.09375 V in 0.00625 V steps.

Thus, in the operation example described above, the potential of the node ND2 of the pixel PIX can have a value ranging from 0 V to 4.8+0.09375 V in 0.00625 V steps from Equations (E2) and (E3), in a period from Time T6 to Time T7.

[The Case where V_{data} has a Value in the Range of 4.9 V to 6.3 V]

Next, the case is described in which V_{data} in the range of 4.9 V to 6.3 V (in the range of “110001” to “111111” in binary notation) is written to the node ND1 and the node ND2 of the pixel PIX.

The capacitance ratio of the capacitor C1 to the capacitor C2 is the same as that when V_{data} has a value in the range of 0 V to 4.8 V; thus, Equation (E3) can also be used in this case.

Here, ΔV_{data} is assumed to have a voltage value in the range of −1.5 V to 0 V in 0.1 V steps, for example. That is, ΔV_{data} is assumed to be a negative value and V_{data}+ΔV_{data} is assumed to be able to have a value in the range of 3.4 V to 6.3 V (in the range of “100010” to “111111” in binary notation).

In this case, from Equation (E3), ΔV_{g} can have a value in the range of −0.09375 V to 0 V in 0.00625 V steps.

Thus, in the operation example described above, the potential of the node ND2 of the pixel PIX can have a value in the range of 4.9-0.09375 V to 6.3 V in 0.00625 V steps from Equations (E2) and (E3), in the period from Time T6 to Time T7.

The above specific example is summarized as follows. When a (6-bit) digital-analog converter circuit capable of outputting an analog value in the range of 0 V to 6.3 V in 0.1 V steps is provided as the digital-analog converter circuit DAC and the capacitance ratio of the capacitor C1 to the capacitor C2 included in the pixel PIX is set to C₁:C₂=1:15, a potential in the range of 0 V to 6.3 V can be applied to the node ND2 in 0.00625 V steps.

That is, by performing the above operation example in the pixel PIX shown in FIG. 4A, a finer voltage value, which cannot be output from the 6-bit digital-analog converter circuit DAC, can be applied to the node ND2. In the above specific example, the digital-analog converter circuit DAC outputs a potential in 0.1 V steps; however, a potential can be written to the node ND2 of the pixel PIX in 0.00625 V steps. In other words, a potential (image data) with higher resolving power than that of the 6-bit digital-analog converter circuit DAC can be written to the pixel PIX.

In the above specific example, ΔV_{data} supplied by the 6-bit digital-analog converter circuit DAC corresponds to high-order 6 bits of image data, and ΔV_{g} that is added to the node ND2 through capacitive coupling of the pixel PIX corresponds to low-order 4 bits of image data. That is, the pixel PIX in FIG. 4A can complement lower 4 bits of image data to higher 6 bits of image data supplied from the digital-analog converter circuit DAC.

Note that the configuration of the pixel PIX of one embodiment of the present invention and the configurations of the wirings electrically connected to the pixel PIX are not limited to those illustrated in FIG. 4A. In one embodiment of the present invention, components of the pixel PIX and each wiring can be changed as appropriate depending on conditions such as design specifications and objectives, for example.

In a specific example, at least one of the transistor Tr1 to the transistor Tr5 included in the pixel PIX in FIG. 4A may be a transistor with a back gate. The threshold voltage of the transistor can be increased or decreased when a potential is applied to the back gate of the transistor.

Electrically connecting a gate and a back gate of the transistor can further increase the amount of source-drain current that flows when the transistor is in an on state. FIG. 4B shows a configuration in which each of the transistor Tr1 to the transistor Tr5 included in the pixel PIX in FIG. 4A is a transistor with a back gate and a gate and a back gate of each of the transistors are electrically connected to each other.

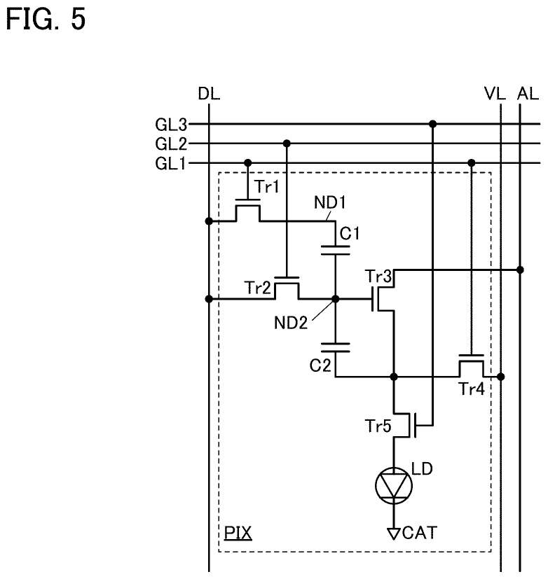

As another specific example, one wiring may double as the wiring DL and the wiring WDL (see FIG. 5). Note that the above operation example is referred to for an operation method of the pixel PIX shown in FIG. 5.

As other specific examples, pixel circuits each including a light-emitting element such as an EL element are shown in FIG. 4A, FIG. 4B, and FIG. 5 in this embodiment; however, one embodiment of the present invention is not limited thereto. One embodiment of the present invention may a configuration in which, for example, a capacitor is also provided for a pixel circuit including a liquid crystal element like in FIG. 4A, FIG. 4B, and FIG. 5, the potential of one terminal of the liquid crystal element is increased or decreased by capacitive coupling, and a finer analog value than the resolving power of the digital-analog converter circuit DAC is supplied.

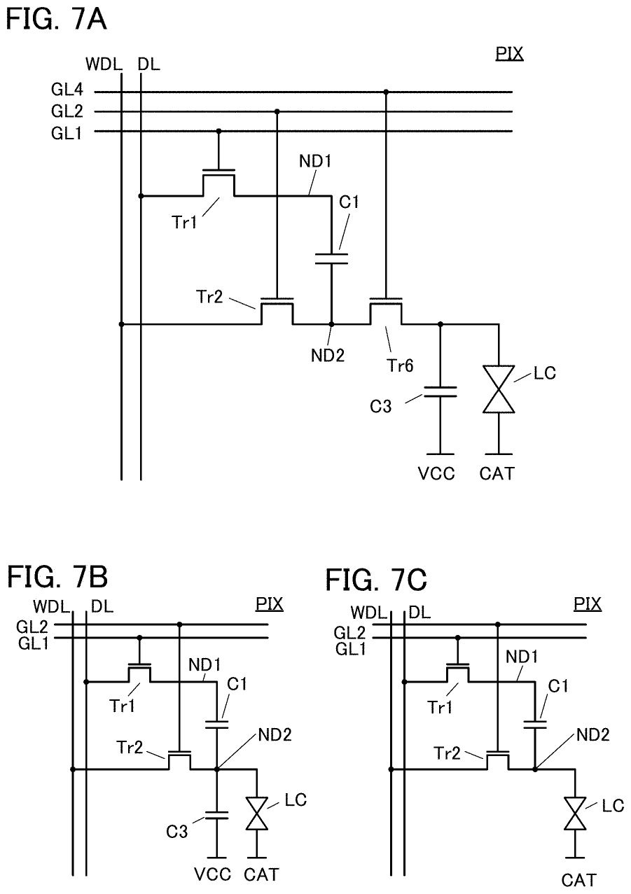

FIG. 7A shows an example in which a liquid crystal element LC is used as a display element. Note that portions different from those described above are mainly described below, and the above descriptions can be referred to for repeating portions.

The pixel PIX shown in FIG. 7A includes the transistor Tr1, the transistor Tr2, a transistor Tr6, the capacitor C1, a capacitor C3, and the liquid crystal element LC. In addition, the wiring GL1, the wiring GL2, a wiring GL4, the wiring DL, the wiring WDL, a wiring VCC, and the wiring CAT are connected to the pixel PIX.

A gate of the transistor Tr6 is electrically connected to the wiring GL4; one of a source and a drain of the transistor Tr6 is electrically connected to the node ND2; and the other of the source and the drain of the transistor Tr6 is electrically connected to one electrode of the capacitor C3 and one electrode of the liquid crystal element LC. The other electrode of the capacitor C3 is electrically connected to the wiring VCC. The other electrode of the liquid crystal element LC is electrically connected to the wiring CAT.

The wiring VCC is a wiring for applying a predetermined potential to the other electrode of the capacitor C3. As a potential applied to the wiring VCC, a fixed potential such as a common potential, a reference potential, or a ground potential can be applied, for example. A configuration may be employed in which the wiring VCC and the wiring CAT are common and supplied with the same potential.

The transistor Tr6 can function as a switch that controls the operation of the liquid crystal element LC. In the case where a signal written from the wiring WDL to the node ND2 is higher than the threshold voltage for operating the liquid crystal element LC, the liquid crystal element LC sometimes operates before an image signal is written from the wiring DL. Thus, it is preferable to provide the transistor Tr6, bring the transistor Tr6 into conduction by a signal supplied to the wiring GL4 after the potential of the node ND2 is determined, and operate the liquid crystal element LC.

The configuration of the pixel PIX shown in FIG. 7B is obtained by omission of the transistor Tr6 and the wiring GL4 from the configuration shown in FIG. 7A.

The transistor Tr6 in FIG. 7A is a switch that prevents unintended operation of the liquid crystal element LC; the transistor Tr6 can be omitted when visual recognition can be prevented even if the liquid crystal element LC operates. For example, operation such as turning off a backlight in a period during which a signal is supplied from the wiring WDL to the node ND2 may be performed in combination.

As shown in FIG. 7C, a configuration without the capacitor C3 may also be employed. An OS transistor can be used as the transistor connected to the node ND2. Since an OS transistor has an extremely low leakage current in an off state, image data can be retained for a comparatively long time even when the capacitor C3 functioning as a storage capacitor is omitted.

This configuration is also effective when frame frequency is high and a period for retaining image data is comparatively short (e.g., field sequential driving). The aperture ratio can be improved by omitting the capacitor C3. Alternatively, the transmittance of the pixel can be improved. Note that the configuration without the capacitor C3 may be applied to the configuration of another pixel circuit shown in this specification.

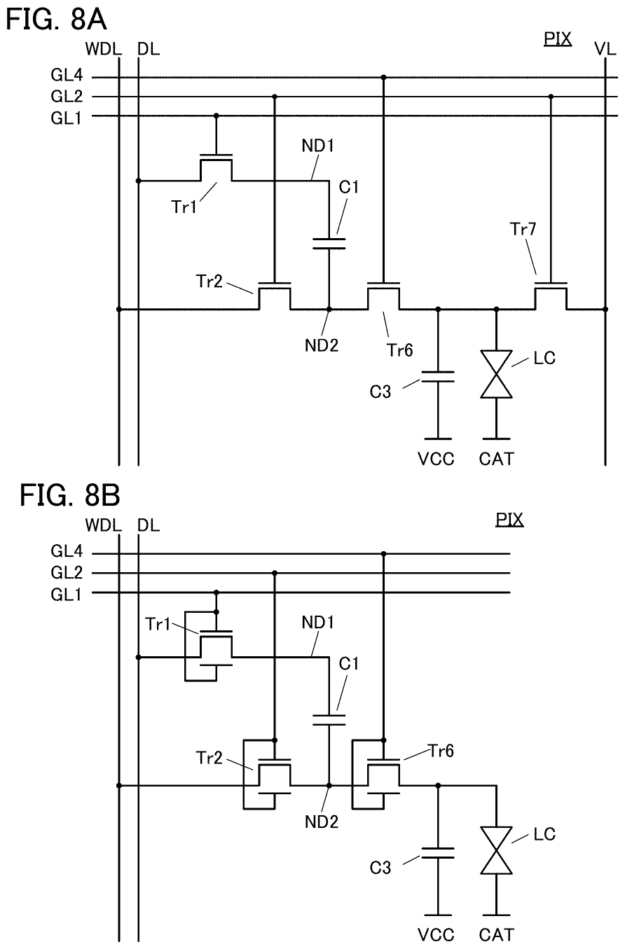

Furthermore, the pixel PIX shown in FIG. 8A is obtained by addition of a transistor Tr7 and the wiring VL to the configuration in FIG. 7A.

In the configuration shown in FIG. 8A, the reset operation of the liquid crystal element LC can be performed by supplying a reset potential to the wiring VL and bringing the transistor Tr7 into conduction. With the configuration, operations of rewriting the potential of the node ND2 and a potential applied to the liquid crystal element LC can be controlled independently, and thus a period for the display operation of the liquid crystal element LC can be lengthened.

In the case where display with low gray levels is performed, the display operation of the liquid crystal element LC may be performed by supplying an image signal from the wiring VL and controlling the conduction and non-conduction of the transistor Tr7. In that case, the transistor Tr6 is always non-conducting.

The pixel PIX shown in FIG. 8B has a configuration in which each transistor is provided with a back gate. The back gate is electrically connected to a front gate and has an effect of increasing an on-state current. In addition, a configuration may be employed in which a fixed potential which is different from that of the front gate can be supplied to the back gate. In such a configuration, the threshold voltage of the transistor can be controlled. Note that although all of the transistors have back gates in FIG. 8B, a transistor without a back gate may be included. Furthermore, a configuration in which a transistor has a back gate is also effective for another pixel circuit in this embodiment.

The above is the description of the configuration examples using the liquid crystal element.

One embodiment of the present invention disclosed in this specification and the like is a semiconductor device including first to third transistors and first and second capacitors. A first terminal of the first transistor is electrically connected to a first terminal of the first capacitor; a first terminal of the second transistor is electrically connected to a gate of the third transistor, a second terminal of the first capacitor, and a first terminal of the second capacitor; and a first terminal of the third transistor is electrically connected to a second terminal of the second capacitor. The semiconductor device has the following first function to fourth function. The first function has functions of setting the first transistor in an on state and writing a first potential to the first terminal of the first capacitor, and functions of setting the second transistor in an on state and writing the first potential to the gate of the third transistor, the second terminal of the first capacitor, and the second terminal of the second capacitor. The second function has functions of setting the second transistor in an off state and retaining the gate potential of the third transistor by the second terminal of the first capacitor and the second terminal of the second capacitor. The third function has a function of writing the sum of the first potential and a third potential to the first terminal of the first capacitor, and a function of changing the first potential retained by the gate of the third transistor, the second terminal of the first capacitor, and the first terminal of the second capacitor into the sum of the first potential and a fourth potential by writing the sum of the first potential and the third potential to the first terminal of the first capacitor. The fourth function has a function of supplying a current corresponding to the sum of the first potential and the fourth potential between the first terminal and the second terminal of the third transistor.

In the above, at least one of the first to third transistors preferably includes a metal oxide in a channel formation region.

In the above, a fourth transistor and a light-emitting element are preferably included. In that case, a first terminal of the fourth transistor is preferably electrically connected to the first terminal of the third transistor and the second terminal of the second capacitor, and an input terminal of the light-emitting element is preferably electrically connected to a second terminal of the fourth transistor.

In the above, the fourth transistor preferably includes a metal oxide in a channel formation region.

In the above, it is preferable that the first potential correspond to high-order bit data and that the fourth potential correspond to low-order bit data.

Another embodiment of the present invention is a display device including the semiconductor device with the above configuration and a digital-analog converter circuit. In that case, an output terminal of the digital-analog converter circuit is preferably electrically connected to the first terminal of the first transistor and the first terminal of the second transistor, and the digital-analog converter circuit preferably has functions of generating the first potential or the sum of the first potential and the third potential and outputting the first potential or the sum of the first potential and the third potential from the output terminal of the digital-analog converter circuit.

Another embodiment of the present invention is an electronic device including the display device with the above structure and a housing.

An operation method of a semiconductor device or a display device of one embodiment of the present invention is not limited to the above operation example or specific example. In the operation method, the sequence of applying a potential to an element, a circuit, a wiring, or the like and the value of the potential can be changed as appropriate, for example. In addition, as described above, the structure of the semiconductor device or the display device of one embodiment of the present invention can be changed as appropriate; thus, the operation method of the semiconductor device or the display device may also be changed depending on the structure.

At least part of this embodiment can be implemented in combination with the other embodiments described in this specification as appropriate.

### Embodiment 3

In this embodiment, structure examples of a display device including an EL element will be described.

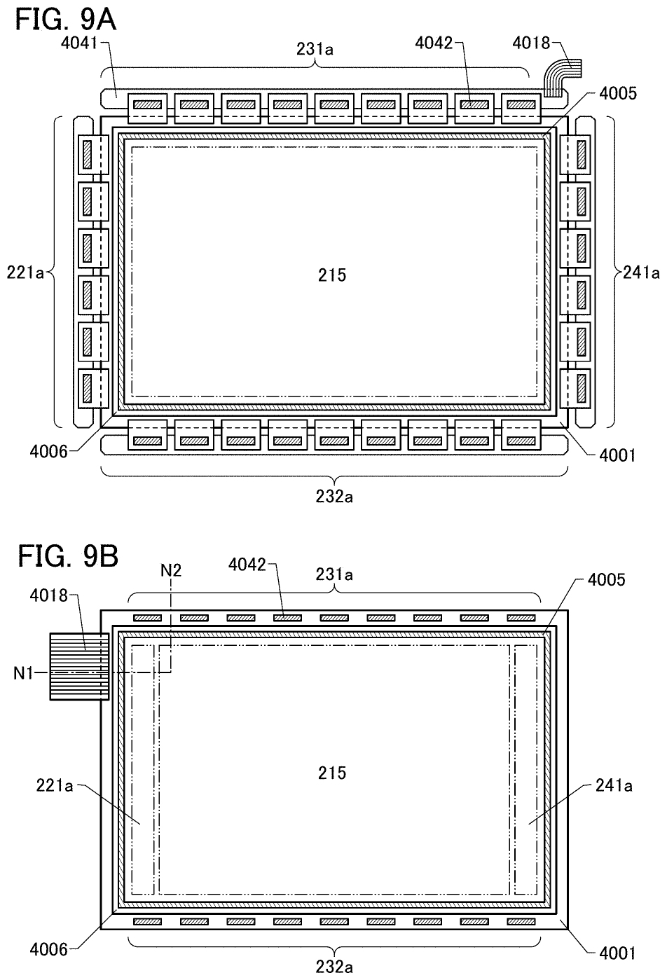

In FIG. 9A, a sealant 4005 is provided to surround a display unit 215 provided over a first substrate 4001, and the display unit 215 is sealed with the sealant 4005 and a second substrate 4006.

A pixel array including the pixels PIX described in Embodiment 1 is provided in the display unit 215.

In FIG. 9A, a scan line driver circuit 221a, a signal line driver circuit 231a, a signal line driver circuit 232a, and a common line driver circuit 241a each include a plurality of integrated circuits 4042 provided over a printed board 4041. The integrated circuits 4042 are formed using a single crystal semiconductor or a polycrystalline semiconductor. The signal line driver circuit 231a and the signal line driver circuit 232a each have a function of the source driver circuit SD described in Embodiment 1. The scan line driver circuit 221a has a function of the gate driver circuit GD described in Embodiment 1. The common line driver circuit 241a has a function of supplying a predetermined potential to the wiring CAT described in Embodiment 1.

A variety of signals and potentials are supplied to the scan line driver circuit 221a, the common line driver circuit 241a, the signal line driver circuit 231a, and the signal line driver circuit 232a through an FPC (Flexible printed circuit) 4018.

The integrated circuits 4042 included in the scan line driver circuit 221a and the common line driver circuit 241a each have a function of supplying a selection signal to the display unit 215. The integrated circuits 4042 included in the signal line driver circuit 231a and the signal line driver circuit 232a each have a function of supplying an image signal to the display unit 215. The integrated circuits 4042 are mounted on regions different from a region surrounded by the sealant 4005 over the first substrate 4001.

Note that there is no particular limitation on the connection method of the integrated circuits 4042; a wire bonding method, a COG (Chip On Glass) method, a TCP (Tape Carrier Package) method, a COF (Chip On Film) method, or the like can be used.

FIG. 9B shows an example of mounting the integrated circuits 4042 included in the signal line driver circuit 231a and the signal line driver circuit 232a by a COG method. Some or all of the driver circuits are integrated over the same substrate as the display unit 215, whereby a system-on-panel can be achieved.

FIG. 9B shows an example in which the scan line driver circuit 221a and the common line driver circuit 241a are formed over the same substrate as the display unit 215. When the driver circuits are formed concurrently with pixel circuits in the display unit 215, the number of components can be reduced. Accordingly, the productivity can be increased.

In FIG. 9B, the sealant 4005 is provided to surround the display unit 215, the scan line driver circuit 221a, and the common line driver circuit 241a, which are provided over the first substrate 4001. Furthermore, the second substrate 4006 is provided over the display unit 215, the scan line driver circuit 221a, and the common line driver circuit 241a. Consequently, the display unit 215, the scan line driver circuit 221a, and the common line driver circuit 241a are sealed together with a display element by the first substrate 4001, the sealant 4005, and the second substrate 4006.

Although the signal line driver circuit 231a and the signal line driver circuit 232a are formed separately and mounted on the first substrate 4001 in the example shown in FIG. 9B, one embodiment of the present invention is not limited to this structure. A scan line driver circuit may be formed separately and mounted, or part of a signal line driver circuit or part of a scan line driver circuit may be formed separately and mounted.

In some cases, the display device includes a panel in which a display element is sealed, and a module in which an IC or the like including a controller is mounted on the panel.

The display unit and the scan line driver circuit provided over the first substrate each include a plurality of transistors. An OS transistor or a Si transistor can be applied to each of the transistors.

A transistor included in a peripheral driver circuit and a transistor included in the pixel circuit of the display unit may have the same structure or different structures. All the transistors included in the peripheral driver circuit may have the same structure or may use the combination of two or more kinds of structures. Similarly, all the transistors included in the pixel circuit may have the same structure or may use the combination of two or more kinds of structures.

An input device can be provided over the second substrate 4006. The structure where the display device shown in FIG. 9 is provided with the input device can function as a touch panel.

There is no limitation on a detection element (also referred to as a sensor element) included in the touch panel of one embodiment of the present invention. A variety of sensors capable of detecting an approach or a contact of a sensing target such as a finger or a stylus can be used as the detection element.

It is possible to use a sensor of any of a variety of types such as a capacitive type, a resistive type, a surface acoustic wave type, an infrared type, an optical type, and a pressure-sensitive type.

In this embodiment, a touch panel including a capacitive detection element is described as an example.

Examples of the capacitive type include a surface capacitive type and a projected capacitive type. Examples of the projected capacitive type include a self-capacitive type and a mutual capacitive type. The use of a mutual capacitive type is preferred because multiple points can be sensed simultaneously.

The touch panel of one embodiment of the present invention can employ a variety of structures such as a structure in which a display device and a detection element that are separately manufactured are attached to each other and a structure in which electrodes and the like included in a detection element are provided on one or both of a substrate supporting a display element and a counter substrate.

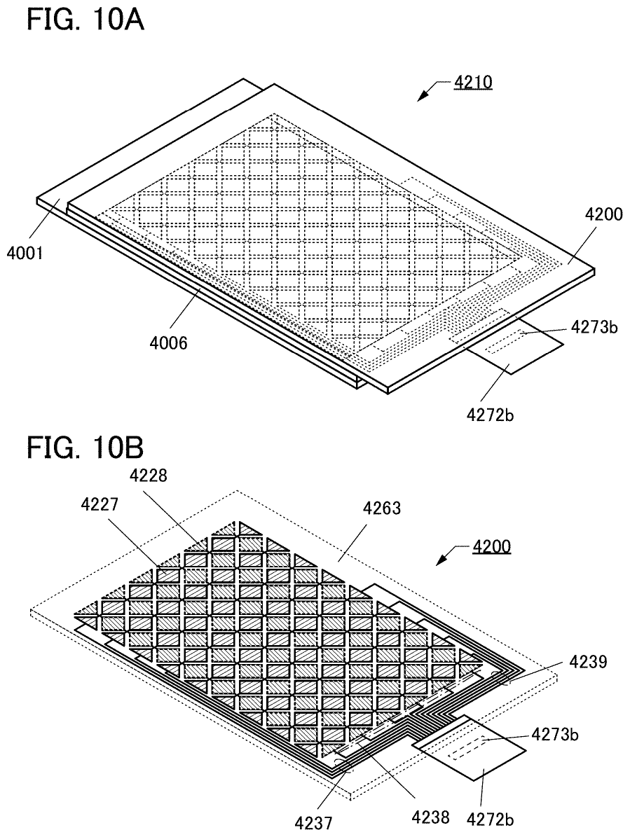

FIG. 10A and FIG. 10B show an example of a touch panel. FIG. 10A is a perspective view of a touch panel 4210. FIG. 10B is a schematic perspective view of the input device 4200. Note that for clarity, only typical components are shown.

The touch panel 4210 has a structure in which a display device and a detection element that are separately manufactured are attached to each other.

The touch panel 4210 includes the input device 4200 and a display device that are provided to overlap with each other.

The input device 4200 includes a substrate 4263, an electrode 4227, an electrode 4228, a plurality of wirings 4237, a plurality of wirings 4238, and a plurality of wirings 4239. For example, the electrode 4227 can be electrically connected to the wiring 4237 or the wiring 4239. In addition, the electrode 4228 can be electrically connected to the wiring 4239. An FPC 4272b is electrically connected to each of the plurality of wirings 4237 and the plurality of wirings 4238. An IC 4273b can be provided on the FPC 4272b.

Alternatively, a touch sensor may be provided between the first substrate 4001 and the second substrate 4006 in the display device. In the case where a touch sensor is provided between the first substrate 4001 and the second substrate 4006, an optical touch sensor using a photoelectric conversion element as well as a capacitive touch sensor may be employed.

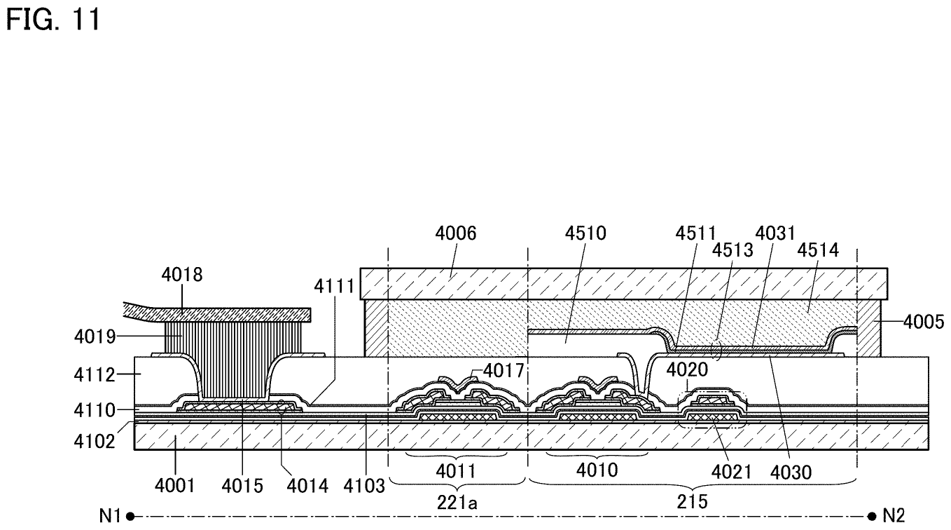

FIG. 11 is a cross-sectional view corresponding to a portion indicated by chain line N1-N2 in FIG. 9B. A display device shown in FIG. 11 includes an electrode 4015, and the electrode 4015 is electrically connected to a terminal included in the FPC 4018 through an anisotropic conductive layer 4019. In FIG. 11, the electrode 4015 is electrically connected to a wiring 4014 in an opening formed in an insulating layer 4112, an insulating layer 4111, and an insulating layer 4110.

The electrode 4015 is formed using the same conductive layer as a first electrode layer 4030, and the wiring 4014 is formed using the same conductive layer as source electrodes and drain electrodes of a transistor 4010 and a transistor 4011.

The display unit 215 and the scan line driver circuit 221a that are provided over the first substrate 4001 each include a plurality of transistors. FIG. 11 shows, as an example, the transistor 4010 included in the display unit 215 and the transistor 4011 included in the scan line driver circuit 221a. Note that in the example shown in FIG. 11, the transistor 4010 and the transistor 4011 are bottom-gate transistors but may be top-gate transistors. Furthermore, the transistor 4011 can be a transistor included in the gate driver circuit GD described in Embodiment 1.

In FIG. 11, the insulating layer 4112 is provided over the transistor 4010 and the transistor 4011. In addition, a partition 4510 is formed over the insulating layer 4112.

The transistor 4010 and the transistor 4011 are provided over an insulating layer 4102. The transistor 4010 and the transistor 4011 each include an electrode 4017 formed over the insulating layer 4111. The electrode 4017 can function as a back gate electrode.

The display device shown in FIG. 11 further includes a capacitor 4020. The capacitor 4020 includes an electrode 4021 formed in the same step as a gate electrode of the transistor 4010, and an electrode formed in the same step as a source electrode and a drain electrode of the transistor 4010. The electrodes overlap with each other with an insulating layer 4103 therebetween. Note that the capacitor 4020 can be the capacitor C1 or the capacitor C2 of the pixel PIX described in Embodiment 1, for example.

The capacitance of a capacitor provided in a pixel portion of a display device is generally set in consideration of the leakage current or the like of transistors placed in the pixel portion so that electric charges can be retained for a predetermined period. The capacitance of the capacitor may be set in consideration of the off-state current or the like of the transistor.

The transistor 4010 provided in the display unit 215 is electrically connected to the display element.

The display device shown in FIG. 11 includes the insulating layer 4111 and the insulating layer 4102. As the insulating layer 4111 and the insulating layer 4102, insulating layers through which impurity elements do not easily pass are used. The transistor is sandwiched between the insulating layer 4111 and the insulating layer 4102, so that entry of impurities into a semiconductor layer from the outside can be prevented.

A light-emitting element utilizing electroluminescence (EL element) can be used as the display element included in the display device. An EL element includes a layer containing a light-emitting compound (also referred to as an “EL layer”) between a pair of electrodes. When a potential difference greater than the threshold voltage of the EL element is generated between the pair of electrodes, holes are injected from an anode side to the EL layer and electrons are injected from a cathode side to the EL layer. The injected electrons and holes are recombined in the EL layer, and a light-emitting substance contained in the EL layer emits light.

EL elements are classified according to whether a light-emitting material is an organic compound or an inorganic compound; in general, the former is referred to as an organic EL element, and the latter is referred to as an inorganic EL element.

In an organic EL element, by voltage application, electrons from one electrode and holes from the other electrode are injected into the EL layer. The carriers (electrons and holes) are then recombined; thus, a light-emitting organic compound forms an excited state, and light is emitted when the excited state returns to a ground state. Owing to such a mechanism, the light-emitting element is referred to as a current-excitation light-emitting element.

Note that in addition to the light-emitting compound, the EL layer may further include a substance with a high hole-injection property, a substance with a high hole-transport property, a hole-blocking material, a substance with a high electron-transport property, a substance with a high electron-injection property, a substance with a bipolar property (a substance with a high electron-transport property and a high hole-transport property), and the like.

The EL layer can be formed by a method such as an evaporation method (including a vacuum evaporation method), a transfer method, a printing method, an inkjet method, or a coating method.

The inorganic EL elements are classified according to their element structures into a dispersion-type inorganic EL element and a thin-film inorganic EL element. A dispersion-type inorganic EL element includes a light-emitting layer where particles of a light-emitting material are dispersed in a binder, and its light emission mechanism is donor-acceptor recombination type light emission that utilizes a donor level and an acceptor level. A thin-film inorganic EL element has a structure in which a light-emitting layer is sandwiched between dielectric layers, which are further sandwiched between electrodes, and its light emission mechanism is localized type light emission that utilizes inner-shell electron transition of metal ions. Note that the description is made here using an organic EL element as a light-emitting element.

In order to extract light emitted from the light-emitting element, at least one of the pair of electrodes is transparent. A transistor and a light-emitting element are formed over a substrate; the light-emitting element can have a top emission structure in which light emission is extracted from the surface on the side opposite to the substrate, a bottom emission structure in which light emission is extracted from the surface on the substrate side, or a dual emission structure in which light emission is extracted from both surfaces. The light-emitting element having any of the emission structures can be used.

FIG. 11 is an example of a light-emitting display device using a light-emitting element as a display element (also referred to as an “EL display device”). A light-emitting element 4513 that is a display element is electrically connected to the transistor 4010 provided in the display unit 215. That is, the transistor 4010 corresponds to the transistor Tr5 described in Embodiment 1, and the light-emitting element 4513 corresponds to the light-emitting element LD described in Embodiment 1. Note that the structure of the light-emitting element 4513 is a stacked-layer structure of the first electrode layer 4030, a light-emitting layer 4511, and the second electrode layer 4031; however, the structure is not limited thereto. The structure of the light-emitting element 4513 can be changed as appropriate depending on, for example, the direction in which light is extracted from the light-emitting element 4513.

The partition 4510 is formed using an organic insulating material or an inorganic insulating material. It is particularly preferable that the partition 4510 be formed using a photosensitive resin material to have an opening portion over the first electrode layer 4030 such that a side surface of the partition 4510 slopes with continuous curvature.

The light-emitting layer 4511 may be formed using a single layer or may be formed such that a plurality of layers are stacked.

The emission color of the light-emitting element 4513 can be white, red, green, blue, cyan, magenta, yellow, or the like depending on the material included in the light-emitting layer 4511.

Examples of a method for achieving color display include a method in which the light-emitting element 4513 whose emission color is white is combined with a coloring layer and a method in which the light-emitting element 4513 with a different emission color is provided in each pixel. The latter method, which requires separate formation of the light-emitting layer 4511 pixel by pixel, is less productive than the former method. However, the latter method enables higher color purity of the emission color than the former method. When the light-emitting element 4513 has a microcavity structure in addition to the latter method, the color purity can be further increased.

Note that the light-emitting layer 4511 may contain an inorganic compound such as quantum dots. For example, when quantum dots are used for the light-emitting layer, the quantum dots can function as a light-emitting material.

A protective layer may be formed over the second electrode layer 4031 and the partition 4510 in order to prevent entry of oxygen, hydrogen, moisture, carbon dioxide, and the like into the light-emitting element 4513. For the protective layer, silicon nitride, silicon nitride oxide, aluminum oxide, aluminum nitride, aluminum oxynitride, aluminum nitride oxide, DLC (Diamond Like Carbon), or the like can be formed. In addition, in a space that is sealed by the first substrate 4001, the second substrate 4006, and the sealant 4005, a filler 4514 is provided for sealing. In this manner, it is preferable that packaging (sealing) be performed with a protective film (such as a laminate film or an ultraviolet curable resin film) or a cover material with high air-tightness and little degasification to prevent exposure to the outside air.

As the filler 4514, an ultraviolet curable resin or a thermosetting resin as well as an inert gas such as nitrogen or argon can be used; and PVC (polyvinyl chloride), an acrylic resin, polyimide, an epoxy resin, a silicone resin, PVB (polyvinyl butyral), EVA (ethylene vinyl acetate), or the like can be used. In addition, a drying agent may be contained in the filler 4514.

For the sealant 4005, a glass material such as a glass frit or a resin material such as a resin that is curable at room temperature (e.g., a two-component-mixture-type resin), a light curable resin, or a thermosetting resin can be used. In addition, a drying agent may be contained in the sealant 4005.

If necessary, an optical film such as a polarizing plate, a circularly polarizing plate (including an elliptically polarizing plate), a retardation plate (a λ/4 plate or a λ/2 plate), or a color filter may be provided as appropriate on a light-emitting surface of the light-emitting element. Furthermore, the polarizing plate or the circularly polarizing plate may be provided with an anti-reflection film. For example, anti-glare treatment that can reduce glare by diffusing reflected light with projections and depressions on a surface can be performed.

In addition, when the light-emitting element has a microcavity structure, light with high color purity can be extracted. Furthermore, when a microcavity structure and a color filter are used in combination, glare can be reduced and the visibility of a displayed image can be increased.

Whether the first electrode layer and the second electrode layer (also referred to as a pixel electrode layer, a common electrode layer, a counter electrode layer, or the like) for applying a voltage to the display element have light-transmitting properties or light-reflecting properties may be determined in accordance with the direction in which light is extracted, the position where the electrode layer is provided, and the pattern structure of the electrode layer.

For the first electrode layer 4030 and the second electrode layer 4031, a light-transmitting conductive material such as indium oxide containing tungsten oxide, indium zinc oxide containing tungsten oxide, indium oxide containing titanium oxide, indium tin oxide, indium tin oxide containing titanium oxide, indium zinc oxide, or indium tin oxide to which silicon oxide is added can be used.

The first electrode layer 4030 and the second electrode layer 4031 can be formed using one or more kinds of metals such as tungsten (W), molybdenum (Mo), zirconium (Zr), hafnium (Hf), vanadium (V), niobium (Nb), tantalum (Ta), chromium (Cr), cobalt (Co), nickel (Ni), titanium (Ti), platinum (Pt), aluminum (Al), copper (Cu), and silver (Ag); alloys thereof; and metal nitrides thereof.

The first electrode layer 4030 and the second electrode layer 4031 can be formed using a conductive composition including a conductive high molecule (also referred to as a conductive polymer). As the conductive high molecule, what is called a π-electron conjugated conductive high molecule can be used. Examples include polyaniline or a derivative thereof, polypyrrole or a derivative thereof, polythiophene or a derivative thereof, and a copolymer of two or more kinds of aniline, pyrrole, and thiophene or a derivative thereof.

Furthermore, since the transistors are easily broken by static electricity or the like, a protective circuit for protecting the driver circuit is preferably provided. The protective circuit is preferably formed using a nonlinear element.

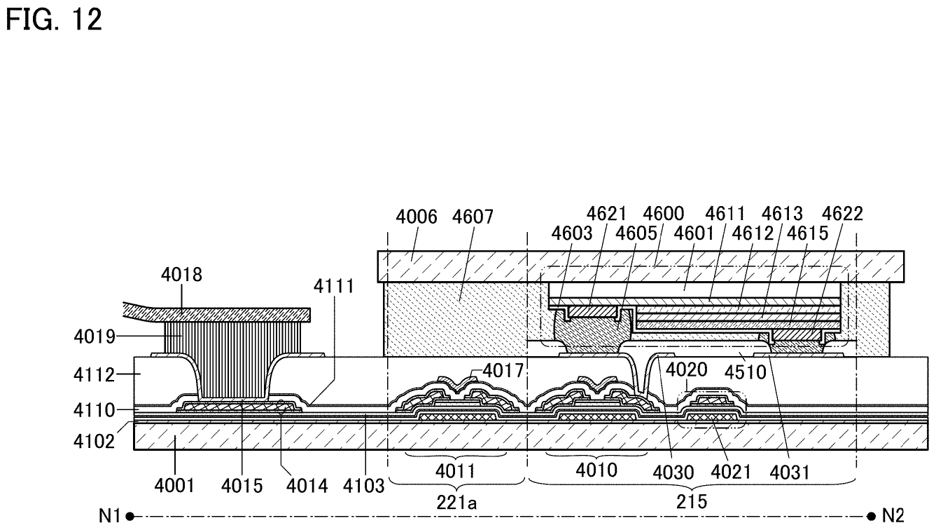

FIG. 12 is an example in which a light-emitting diode chip (hereinafter also referred to as an LED chip) is used as a display element.

The LED chip includes a light-emitting diode. There is no particular limitation on the structure of the light-emitting diode; an MIS (Metal Insulator Semiconductor) junction may be used or a homostructure, a heterostructure, a double-heterostructure, or the like having a PN junction or a PIN junction can be used. It is also possible to use a superlattice structure, or a single quantum well structure or a multi quantum well (MQW) structure where thin films producing a quantum effect are stacked.

An LED chip 4600 includes a substrate 4601, an n-type semiconductor layer 4611, a light-emitting layer 4612, a p-type semiconductor layer 4613, an electrode 4615, an electrode 4621, an electrode 4622, an insulating layer 4603, and the like.

A material that has larger band gap energy than the light-emitting layer 4612 and allows carriers to be trapped in the light-emitting layer 4612 can be used as a material of the p-type semiconductor layer 4613. In addition, in the LED chip 4600, the electrode 4621 functioning as a cathode is provided over the n-type semiconductor layer 4611, the electrode 4615 functioning as a contact electrode is provided over the p-type semiconductor layer 4613, and the electrode 4622 functioning as an anode is provided over the electrode 4615. Furthermore, a top surface of the n-type semiconductor layer 4611 and a top surface and a side surface of the electrode 4615 are preferably covered with the insulating layer 4603. The insulating layer 4603 functions as a protective film of the LED chip 4600.

The LED chip 4600 can have a light emission area of less than or equal to 1 mm², preferably less than or equal to 10000 μm², further preferably less than or equal to 3000 μm², still further preferably less than or equal to 700 μm².

A macro LED whose one side dimension is greater than 1 mm may be used as the LED chip 4600; however, a smaller LED is preferably used. In particular, a mini LED whose one side dimension is greater than 100 μm and less than or equal to 1 mm is preferably used, and further preferably, a micro LED whose one side dimension is less than or equal to 100 μm is used. The use of a micro LED can achieve an extremely high-resolution display device.

The n-type semiconductor layer 4611 may have a stacked-layer structure of an n-type contact layer on the substrate 4601 side and an n-type clad layer on the light-emitting layer 4612 side. In addition, the p-type semiconductor layer 4613 may have a stacked-layer structure of a p-type clad layer on the light-emitting layer 4612 side and a p-type contact layer on the electrode 4615 side.

A multi quantum well (MQW) structure where a barrier layer and a well layer are stacked more than once can be used as the light-emitting layer 4612. For the barrier layer, it is preferable to use a material having larger band gap energy than the well layer. Such a structure allows the energy to be trapped in the well layer, which can improve quantum efficiency and the emission efficiency of the LED chip 4600.

The LED chip 4600 is a face-down type LED chip where light is mainly emitted to the substrate 4601 side. In that case, a material that reflects light can be used for the electrode 4615; for example, a metal such as silver, aluminum, or rhodium can be used. Note that in the case where a face-up type LED chip is used, a light-transmitting material is used for the electrode 4615; for example, an oxide such as ITO (In₂O₃—SnO₂), AZO (Al₂O₃—ZnO), IZO (Registered mark) (In₂O₃—ZnO), GZO (GeO₂—ZnO), or ICO (In₂O₃—CeO₂) can be used.

For the substrate 4601, oxide single crystal such as sapphire single crystal (Al₂O₃), spinel single crystal (MgAldO₄), ZnO single crystal, LiAlO₂ single crystal, LiGaO₂ single crystal, or MgO single crystal; Si single crystal; SiC single crystal; GaAs single crystal; AN single crystal; GaN single crystal; boride single crystal such as ZrB₂; or the like can be used. In the LED chip 4600 of a face-down type, a light-transmitting material is preferably used for the substrate 4601; for example, sapphire single crystal or the like can be used.

A buffer layer (not shown) may be provided between the substrate 4601 and the n-type semiconductor layer 4611. The buffer layer has a function of alleviating the difference in lattice constant between the substrate 4601 and the n-type semiconductor layer 4611.

The electrode 4621 and the electrode 4622 included in the LED chip 4600 are bonded to the first electrode layer 4030 and the second electrode layer 4031, respectively, through bumps 4605.

In addition, a light-blocking resin layer 4607 is preferably provided to cover side surfaces of the LED chip 4600. Accordingly, light emitted from the LED chip 4600 in a lateral direction can be blocked, and the decrease in contrast due to waveguide light can be prevented.

FIG. 12 shows an example where the substrate 4006 is further included over the substrate 4601. When the resin layer 4607 is provided around the LED chip 4600 and a top surface of the LED chip 4600 is covered with the substrate 4006 in this manner, bonding of the LED chip 4600 can be further strengthened, and bonding defects of the LED chip 4600 can be favorably prevented.

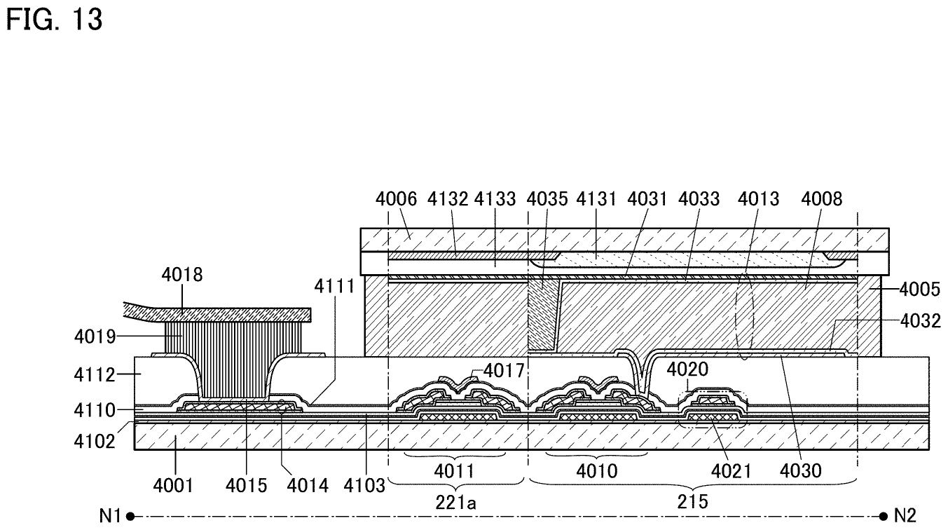

FIG. 13 is an example of a liquid crystal display device using a liquid crystal element as a display element.

In FIG. 13, a liquid crystal element 4013 that is a display element includes the first electrode layer 4030, the second electrode layer 4031, and a liquid crystal layer 4008. Note that an insulating layer 4032 and an insulating layer 4033 functioning as alignment films are provided so that the liquid crystal layer 4008 is positioned therebetween. The second electrode layer 4031 is provided on the second substrate 4006 side, and the first electrode layer 4030 and the second electrode layer 4031 overlap with each other with the liquid crystal layer 4008 therebetween.

A spacer 4035 is a columnar spacer obtained by selective etching of an insulating layer and is provided to control the distance (cell gap) between the first electrode layer 4030 and the second electrode layer 4031. Note that a spherical spacer may be used.

A black matrix (light-blocking layer), a coloring layer (color filter), an optical member (optical substrate) such as a polarizing member, a retardation member, or an anti-reflection member, and the like may be provided as appropriate if needed. For example, circular polarization using a polarizing substrate and a retardation substrate may be employed. Furthermore, a backlight, a side light, or the like may be used as a light source. Moreover, a micro LED or the like may be used as the backlight or the side light.

In the display device shown in FIG. 13, a light-blocking layer 4132, a coloring layer 4131, and an insulating layer 4133 are provided between the substrate 4006 and the second electrode layer 4031.

Examples of a material that can be used for the light-blocking layer include carbon black, titanium black, a metal, a metal oxide, and a composite oxide containing a solid solution of a plurality of metal oxides. The light-blocking layer may be a film containing a resin material or may be a thin film of an inorganic material such as a metal. A stacked-layer film containing the material of the coloring layer can also be used for the light-blocking layer. For example, it is possible to employ a stacked-layer structure of a film containing a material used for a coloring layer that transmits light of a certain color and a film containing a material used for a coloring layer that transmits light of another color. It is preferable that the coloring layer and the light-blocking layer be formed using the same material because the same apparatus can be used and the process can be simplified.

Examples of a material that can be used for the coloring layer include a metal material, a resin material, and a resin material containing a pigment or dye. The light-blocking layer and the coloring layer may be formed by a method similar to the method for forming each layer. For example, the light-blocking layer and the coloring layer may be formed by an inkjet method or the like.

At least part of this embodiment can be implemented in combination with the other embodiments described in this specification as appropriate.

### Embodiment 4

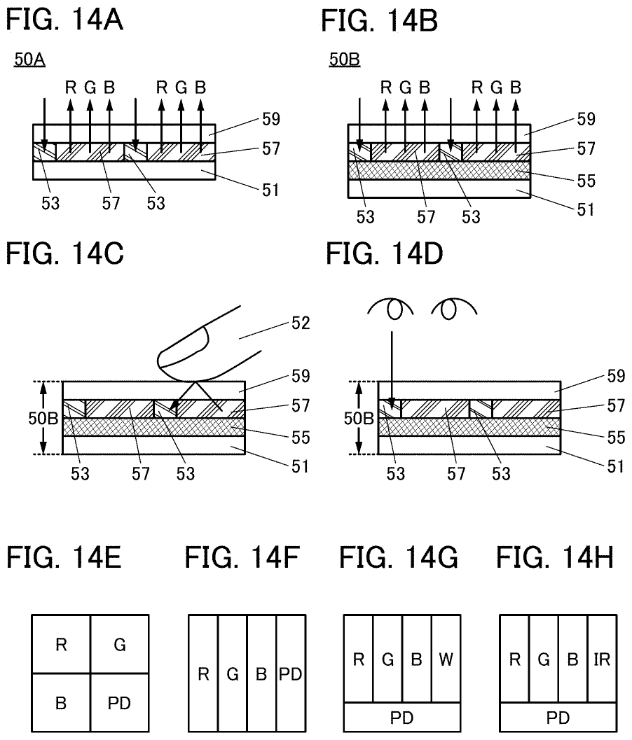

In this embodiment, a display device of one embodiment of the present invention will be described with reference to FIG. 14.

A display device described below as an example is a device having a function of displaying an image and a function of capturing an image. The display device described below as an example can be used for the display unit in Embodiment 1.

### [Overview]

The display device of this embodiment includes light-receiving elements and light-emitting elements in a display unit. Specifically, the light-emitting elements are arranged in a matrix in the display unit, and an image can be displayed on the display unit. Moreover, the light-receiving elements are arranged in a matrix in the display unit, so that the display unit also has a function of a light-receiving portion. The light-receiving portion can be used as an image sensor or a touch sensor. That is, by sensing light with the light-receiving portion, an image can be captured and the approach or contact of an object (e.g., a finger or a stylus) can be sensed.

In the display device of this embodiment, when an object reflects light emitted from the light-emitting element included in the display unit, the light-receiving element can sense the reflected light; thus, imaging and touch (including near touch) sensing are possible even in a dark place.

The display device of this embodiment has a function of displaying an image with the use of a light-emitting element. That is, the light-emitting element functions as a display element.

As the light-emitting element, an EL element such as an OLED (Organic Light Emitting Diode) or a QLED (Quantum-dot Light Emitting Diode) is preferably used. As the light-emitting substance contained in the EL element, a substance emitting fluorescence (a fluorescent material), a substance emitting phosphorescence (a phosphorescent material), an inorganic compound (e.g., a quantum dot material), a substance exhibiting thermally activated delayed fluorescence (a thermally activated delayed fluorescent (TADF) material), or the like can be given. Alternatively, a light-emitting diode (LED) such as a micro-LED can be used as the light-emitting element.

The display device of this embodiment has a function of sensing light with the use of a light-receiving element.

In the case where the light-receiving element is used as an image sensor, an image can be captured with the use of the light-receiving element in the display device of this embodiment.

In the case where the light-receiving element is used as an illuminance sensor, the illuminance of external light and chromaticity can be measured with the use of the light-receiving element in the display device of this embodiment.

For example, data on a fingerprint, a palm print, an iris, or the like can be acquired with the use of the image sensor. That is, a biological authentication sensor can be incorporated into the display device of this embodiment. When the display device incorporates a biological authentication sensor, the number of components of an electronic device can be reduced as compared to the case where a biological authentication sensor is provided separately from the display device; thus, the size and weight of the electronic device can be reduced.

In addition, data on facial expression, eye movement, change of the pupil diameter, or the like of the user can be acquired with the use of the image sensor. By analysis of the data, data on the user's physical and mental state can be acquired. Changing the output contents of one or both of display and sound on the basis of the data allows the user to safely use a device for VR (Virtual Reality), a device for AR (Augmented Reality), or a device for MR (Mixed Reality), for example.

In the case where the light-receiving element is used as the touch sensor, the display device of this embodiment can sense the approach or contact of an object with the use of the light-receiving element.

As the light-receiving element, a PN photodiode or a PIN photodiode can be used, for example. The light-receiving element functions as a photoelectric conversion element that senses light incident on the light-receiving element and generates electric charge. The amount of generated electric charge depends on the amount of incident light.

It is particularly preferable to use an organic photodiode including a layer containing an organic compound as the light-receiving element. An organic photodiode, which is easily made thin, lightweight, and large in area and has a high degree of freedom for shape and design, can be used in a variety of display devices.

In one embodiment of the present invention, organic EL elements are used as the light-emitting elements, and organic photodiodes are used as the light-receiving elements. A large number of layers of the organic photodiode can be shared with the organic EL element. Accordingly, the light-receiving element can be incorporated into the display device without a significant increase in the number of manufacturing steps. For example, an active layer of the light-receiving element and a light-emitting layer of the light-emitting element are separately formed, and the other layers can be shared by the light-emitting element and the light-receiving element.

FIG. 14A to FIG. 14D show cross-sectional views of display devices of embodiments of the present invention.

A display device 50A shown in FIG. 14A includes a layer 53 including a light-receiving element and a layer 57 including a light-emitting element between a substrate 51 and a substrate 59.

A display device 50B shown in FIG. 14B includes the layer 53 including a light-receiving element, a layer 55 including transistors, and the layer 57 including a light-emitting element between the substrate 51 and the substrate 59.

In the display device 50A and the display device 50B, red (R) light, green (G) light, and blue (B) light are emitted from the layer 57 including a light-emitting element.

The display device of one embodiment of the present invention includes a plurality of pixels arranged in a matrix. One pixel includes one or more subpixels. One subpixel includes one light-emitting element. For example, the pixel can have a structure including three subpixels (e.g., three colors of R, G, and B or three colors of yellow (Y), cyan (C), and magenta (M)) or four subpixels (e.g., four colors of R, G, B, and white (W) or four colors of R, G, B, and Y). The pixel further includes a light-receiving element. The light-receiving element may be provided in all the pixels or may be provided in some of the pixels. In addition, one pixel may include a plurality of light-receiving elements.

The layer 55 including transistors preferably includes a first transistor and a second transistor. The first transistor is electrically connected to the light-receiving element. The second transistor is electrically connected to the light-emitting element.

The display device of one embodiment of the present invention may have a function of sensing an object such as a finger that is touching the display device. For example, light emitted from the light-emitting element in the layer 57 including the light-emitting element is reflected by a finger 52 that touches the display device 50B as shown in FIG. 14C; then, the light-receiving element in the layer 53 including the light-receiving element senses the reflected light. Thus, the touch of the finger 52 on the display device 50B can be sensed.

The display device of one embodiment of the present invention may have a function of sensing an object that is approaching (but is not touching) the display device 50B as shown in FIG. 14D or capturing an image of such an object.

FIG. 14E to FIG. 14H show examples of pixels.

The pixels shown in FIG. 14E and FIG. 14F each include three subpixels (three light-emitting elements) of R, G, and B and a light-receiving element PD. FIG. 14E shows an example in which the three subpixels and the light-receiving element PD are arranged in a 2×2 matrix, and FIG. 14F shows an example in which the three subpixels and the light-receiving element PD are arranged horizontally in one line.

The pixel shown in FIG. 14G includes four subpixels (four light-emitting elements) of R, G, B, and W and the light-receiving element PD.

The pixel shown in FIG. 14H includes three subpixels of R, G, and B, a light-emitting element IR that emits infrared light, and the light-receiving element PD. Here, the light-receiving element PD preferably has a function of sensing infrared light. The light-emitting element PD may have a function of sensing both visible light and infrared light. The wavelength of light that the light-receiving element PD senses can be determined depending on the application of the sensor.

### Embodiment 5

In this embodiment, a data processing device of one embodiment of the present invention will be described.

Actions of the human depend on emotions at that time. The human can control emotions unconsciously in many cases; thus, when a relatively small stimulus inducing a change in emotions is applied, the human can keep his/her mind calm. However, when a great stimulus inducing a change in emotions is applied, the human cannot control emotions well and thus might unconsciously take actions on the basis of emotions.

Such a change in emotions might reduce concentration. When concentration is reduced, for example, the work efficiency or the work accuracy is decreased even in the case where the same work is carried out. A reduction in concentration due to emotions sometimes causes an accident or disaster. In particular, when the human drives a car or the like, a reduction in concentration may lead to an extremely dangerous accident.

One embodiment of the present invention detects part (in particular, an eye or an eye and its vicinity) or the whole of a user's face, extracts features of the user's face from data on the part or the whole of the face sensed, and estimates the user's emotions from the extracted features of the face. In the case where the estimated emotions might reduce concentration, for example, a stimulus is applied to the sense of sight, the sense of hearing, the sense of touch, the sense of smell, or the like of the user to recover the concentration of the user. This can effectively inhibit a reduction in the concentration that is not recognized by the user.

Examples of the emotions that might reduce concentration or the like include irritation, impatience, anger, indignation, sadness, excitement, anxiety, fear, dissatisfaction, suffering, and emptiness. Hereinafter, these emotions are collectively referred to as negative emotions in some cases. Note that in general, excitement is not limited to the negative emotions; here, excitement is an emotion that might reduce concentration or the like and thus is included in the negative emotions.

A stimulus is applied to the user preferably through the sense of sight. For example, an image that dispels the negative emotions of the user and calms down the user's mind can be displayed. Examples of such an image include an image relating to the nature such as an animal, a plant, and scenery. Note that the image that calms down the user's mind depends on the individuals; thus, a method may be employed in which an image set by the user in advance is displayed.

A stimulus applied to the user through the sense of sight may be a change in a color tone of a displayed image. For example, the tone of red is lowered and the tone of green or blue is raised in the color tone of a displayed image, so that the negative emotions of the user can be suppressed and the user can calm down. In that case, an instant and extreme change in the color tone may lead to an adverse effect such as an increase in irritation of the user; thus, the color tone is preferably changed gradually over time to the extent that the user hardly perceives the change. For example, in the case where an image can be displayed with 256 or more gray levels of each color, the color tone is gradually changed such that a gray level value changed in one second is lower than or equal to 1.

Examples of the stimulus that is applied to the user through the sense of sight include a gradual decrease in the brightness of a space where the user is present and the color tone of lighting that is made close to green or blue.

Examples of a stimulus that is applied through the sense of hearing to dispel the negative emotions of the user and calm down the user's mind include an environmental sound relating to the nature (e.g., a bird song and the sound of flowing water).

A reduction in the concentration or the like of the user can be suitably inhibited by making the user realize the estimated current emotion instead of applying a stimulus for calming down the user's mind to the user. When recognizing the negative emotions which the user is not aware of, the user can consciously take actions to calm down the user's mind. For example, the user can consciously take a deep breath and take a rest by stopping the work or the driving.

As a method for making the user recognize the current emotion, a character whose facial expression is close to the current emotion of the user can be displayed on a screen and an image in which the level of the emotion (e.g., the level of irritation) is quantified or graphically represented can be displayed on a screen, for example. Alternatively, in the case where the user is estimated to significantly get emotional, for example, an alert can be issued to the user with the use of a sound, lighting, a smell, or the like. In particular, when an alert is issued through the sense of sight using display of an image at the same time as an alert that affects the sense of hearing, the sense of smell, the sense of touch, or the like, the user can recognize the current emotion more effectively.

A method for estimating the user's emotions is described. First, an image of part of the face of the user (subject) including an eye or an eye and its vicinity is captured. Then, features of the face are extracted from the captured part of the user's face. After that, the current emotion of the user is estimated from the extracted features of the face. The feature extraction and the emotion estimation can be suitably performed by inference using a neural network.

More specific examples are described below with reference to drawings.

### [Structure Example]

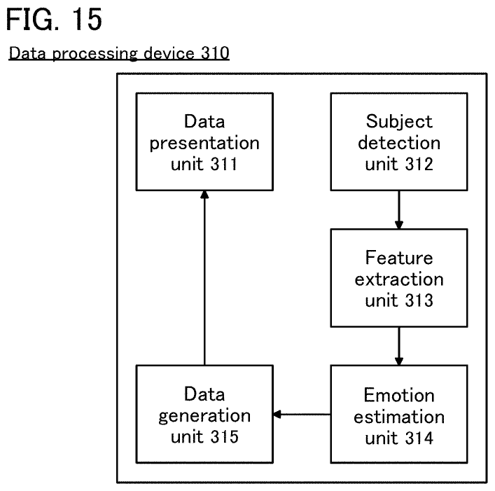

FIG. 15 is a block diagram of a data processing device 310 of one embodiment of the present invention. The data processing device 310 includes a data presentation unit 311, a subject detection unit 312, a feature extraction unit 313, an emotion estimation unit 314, and a data generation unit 315.

Note that in the drawings attached to this specification, the block diagram in which components are classified according to their functions and shown as independent blocks is shown; however, it is difficult to separate actual components completely according to their functions, and one component may be related to a plurality of functions or a plurality of components may achieve one function.

### [Data Presentation Unit 311]

The data presentation unit 311 has a function of applying a stimulus to the sense of sight, the sense of smell, the sense of hearing, or the sense of touch of the user. The data presentation unit 311 can present (output) data generated in the after-mentioned data generation unit 315 to the user.

Various kinds of hardware can be used for the data presentation unit 311. For example, in the case where a stimulus is applied to the sense of sight of the user (or data is presented), a display device capable of displaying images, a lighting device with variable illuminance or chromaticity, or the like can be used. As a device for applying a stimulus to the sense of smell, an aromatherapy diffuser that diffuses scent by vibration, heat, or the like can be used, for example. As a device for applying a stimulus to the sense of hearing, an audio output device such as a speaker, headphones, or earphones can be used. As a device for applying a stimulus to the sense of touch, a vibrator or the like can be used.

It is particularly preferable that the data processing device 310 of one embodiment of the present invention present data to the user through the sense of sight. In the case where the data presentation unit 311 included in the data processing device 310 has an image display unit, the data processing device can be called an image display device.

Furthermore, the data presentation unit 311 preferably includes another data presentation unit besides the image display unit. In that case, an image can be presented to the user and a stimulus can be applied to the sense of sight, the sense of hearing, the sense of smell, or the sense of touch by another means, so that notice can be synergistically given to the user.

### [Subject Detection Unit 312]

The subject detection unit 312 has a function of obtaining data on part of the user's face and outputting the data to the feature extraction unit 313.

As the subject detection unit 312, an imaging device including an image sensor can be typically used. In that case, an infrared imaging device that captures an image by irradiating the user's face with infrared rays may be used. Note that the subject detection unit 312 is not limited to an imaging device as long as a device can sense the state of part of the subject's face. An optical distance measurement device that measures the distance between the device and part of the face with the use of infrared rays or the like can also be used. A sensing device that makes an electrode contact with the user's face to electrically sense muscle movement of the user's face may be used.

### [Feature Extraction Unit 313]

The feature extraction unit 313 has a function of extracting feature points from the facial data output from the subject detection unit 312, extracting features of part or the whole of the face from the position of the feature points, and outputting data on the extracted features to the emotion estimation unit 314.

When facial data obtained by the subject detection unit 312 is data on the eye and its vicinity, examples of features that the feature extraction unit 313 extracts include a pupil, an iris, a cornea, a conjunctiva (the white of the eye), an inner canthus, an outer canthus, an upper eyelid, a lower eyelid, eyelashes, an eyebrow, a glabella, an inner end of an eyebrow, and an outer end of an eyebrow. Examples of features other than the eye and its vicinity include a nasal root, a nasal apex, a nasal bridge, a nostril, lips (an upper lip and a lower lip), a corner of the mouth, an oral aperture, teeth, a cheek, a chin, a jaw, and a forehead. The feature extraction unit 313 recognizes the shape, position, and the like of these facial parts and extracts the position coordinates of the feature point of each part. Then, data on the extracted position coordinates or the like can be output to the emotion estimation unit 314 as data on the facial features.

As a method for extracting features by the feature extraction unit 313, a variety of algorithms for extracting a feature point from an image or the like obtained by the subject detection unit 312 can be employed. For example, an algorithm such as SIFT (Scaled Invariant Feature Transform), SURF (Speeded Up Robust Features), or HOG (Histograms of Oriented Gradients) can be used.

In particular, feature extraction by the feature extraction unit 313 is preferably performed by neural network inference. It is particularly preferable to use convolutional neural networks (CNN). The case of using a neural network will be described below.

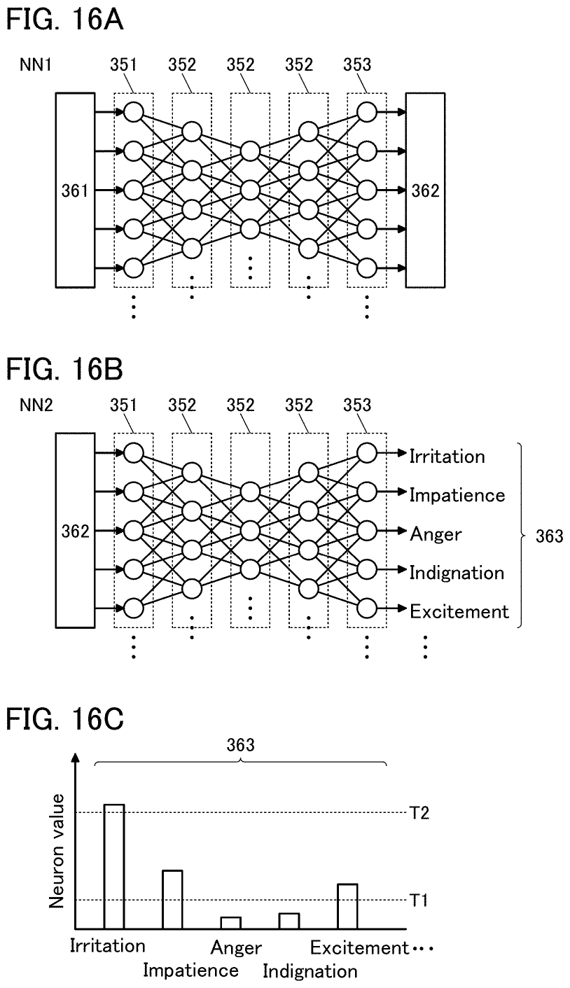

FIG. 16A schematically shows a neural network NN1 that can be used in the feature extraction unit 313. The neural network NN1 includes an input layer 351, three intermediate layers 352, and an output layer 353. Note that the number of intermediate layers 352 is not limited to three and can be one or more.

Data 361 input from the subject detection unit 312 is input to the neural network NN1. The data 361 is data that includes coordinates and a value corresponding to the coordinates. The data 361 can be typically image data that includes coordinates and a gray level corresponding to the coordinates. Data 362 is output from the neural network NN1. The data 362 is data that includes the position coordinates of the aforementioned feature point.

The neural network NN1 has learned in advance so as to extract the aforementioned feature point from the data 361 such as image data and output its coordinates. The neural network NN1 has learned such that edge computing using various filters or the like in the intermediate layers 352 increases a neuron value of the output layer 353 corresponding to the coordinates of the aforementioned feature point.

### [Emotion Estimation Unit 314]

The emotion estimation unit 314 has a function of estimating the user's emotions from data on the features of the face input from the feature extraction unit 313 and outputting data on the estimated emotions to the data generation unit 315.

The emotion estimation unit 314 can estimate whether or not the user feels the negative emotions (e.g., irritation, impatience, anger, indignation, sadness, excitement, anxiety, fear, dissatisfaction, suffering, and emptiness) with the use of the data on the features of the user's face. In the case where the user feels the negative emotions, the degree (level) thereof is preferably estimated.

Emotion estimation in the emotion estimation unit 314 is preferably performed by neural network inference. It is particularly preferable to use a CNN.

FIG. 16B schematically shows a neural network NN2 that can be used in the emotion estimation unit 314. Shown here is an example where the neural network NN2 has substantially the same structure as the neural network NN1. Note that the number of neurons of the input layer 351 in the neural network NN2 can be smaller than that in the neural network NN1.

The data 362 input from the feature extraction unit 313 is input to the neural network NN2. The data 362 includes data on the coordinates of the extracted feature point.

As data input to the neural network NN2, data obtained by processing the data 362 may be used. For example, data obtained by performing calculation of a vector connecting given two feature points on all of the feature points or some of the feature points may be used as data input to the neural network NN2. Moreover, data obtained by normalizing the calculated vectors may be used. Note that hereinafter, data obtained by processing the data 362 output from the neural network NN1 is also referred to as the data 362.

Data 363 is output from the neural network NN2 to which the data 362 is input. The data 363 corresponds to neuron values output from respective neurons of the output layer 353. Each neuron of the output layer 353 is associated with one emotion. As shown in FIG. 16B, the data 363 is data that includes neuron values of the neurons each corresponding to a predetermined negative emotion (e.g., irritation, impatience, anger, indignation, and excitement).

The neural network NN2 has learned in advance so as to estimate the degree of the negative emotions from the data 362 and output the estimation as neuron values. The facial expression of the user can be determined by the relative positional relationship between a plurality of feature points on the user's face. Thus, the user's emotion can be estimated from the facial expression by the neural network NN2.

FIG. 16C is a diagram schematically showing data 363. The level of a neuron value corresponding to each emotion indicates the degree of an estimated emotion. A threshold value T1 and a threshold value T2 are indicated by dashed lines in the data 363. For example, when a neuron value is below the threshold value T1, it can be determined that the user does not feel the corresponding emotion or the degree of the corresponding emotion is sufficiently low. When a neuron value exceeds the threshold value T2, the degree of the corresponding emotion can be determined to be noticeably high.

For example, it can be estimated from FIG. 16C that the user feels an emotion in which “irritation”, “impatience”, and “excitement” are mixed; in particular, the user strongly feels “irritation”.

As described above, the emotion estimation unit 314 estimates only the negative emotions and outputs the results to the data generation unit 315, so that the scale of the arithmetic operation in the emotion estimation unit 314 can be reduced, resulting in a reduction in power consumed in the arithmetic operation. In addition, the amount of data used in the data generation unit 315 can be reduced; thus, power consumed in the data transmission from the emotion estimation unit 314 to the data generation unit 315 and the arithmetic operation in the data generation unit 315 can also be reduced. Note that the emotion estimation unit 314 can estimate not only the negative emotions but also emotions opposite thereto, such as joy, appreciation, happiness, familiarity, satisfaction, and affection, and can output the results to the data generation unit 315.

Note that the emotion estimation can also be performed without using a neural network. For example, estimation may be performed by a template matching method or a pattern matching method, where an image of part of the user's face, which is obtained by the subject detection unit 312, is compared with a template image to use the degree of similarity therebetween. In that case, a structure without the feature extraction unit 313 can also be employed.

### [Data Generation Unit 315]

The data generation unit 315 has a function of determining or generating data to be presented to the user on the basis of the emotion estimated by the emotion estimation unit 314 and outputting the data to the data presentation unit 311.

For example, when the data presentation unit 311 has a function of displaying images, the data generation unit 315 can generate or select an image to be displayed and output the data thereon to the data presentation unit 311. When the data presentation unit 311 has a function of a lighting device, the data generation unit 315 can determine the brightness (illuminance) and chromaticity of lighting and output the data to the data presentation unit 311. When the data presentation unit 311 has a function of diffusing scent, the data generation unit 315 can determine the type or strength of scent to be diffused and output a signal for controlling the operation of the data presentation unit 311, for example. When the data presentation unit 311 has a function of outputting a sound, the data generation unit 315 can generate or select a sound to be reproduced and output the data thereon as well as data on the volume level for reproduction to the data presentation unit 311. When the data presentation unit 311 has a function of producing a vibration, the data generation unit 315 can determine the pattern and intensity of the vibration and output a signal for controlling the operation of the data presentation unit 311, for example.

The above is the description of the structure example of the data processing device 310.

The components included in the data processing device 310 and their functions can be incorporated in the composite device (also referred to as the composite system) such as the electronic device 100 shown in Embodiment 1.

Here, one embodiment of the present invention described in Embodiment 1 and the like can also be referred to as a composite device that includes a display unit, an imaging unit, and an illuminance sensing unit and has a function of detecting that a user sees the display unit by the imaging unit, a function of measuring external illuminance by the illuminance sensing unit in the case where the user sees the display unit, and a function of correcting the luminance of the display unit in accordance with the value of the measured external illuminance and displaying an image.

The composite device of one embodiment of the present invention can have a function of sensing part or the whole of a user's face by the imaging unit, a function of estimating a user's emotion from data of the part or the whole of the face sensed, and a function of supplying data to the user by the display unit in accordance with the estimated emotion.

The composite device of one embodiment of the present invention preferably includes an audio output unit. In that case, the composite device preferably has a function of supplying data to the user with sound by the audio output unit.

At least part of this embodiment can be implemented in combination with the other embodiments described in this specification as appropriate.

### Embodiment 6

In this embodiment, structures of transistors that can be used in the semiconductor device or the display device of one embodiment of the present invention will be described.

The semiconductor device or the display device of one embodiment of the present invention can be fabricated by using a transistor with any of various modes, such as a bottom-gate transistor or a top-gate transistor. Therefore, a material used for a semiconductor layer or a transistor structure can be easily changed depending on the existing production line.

### [Bottom-Gate Transistor]

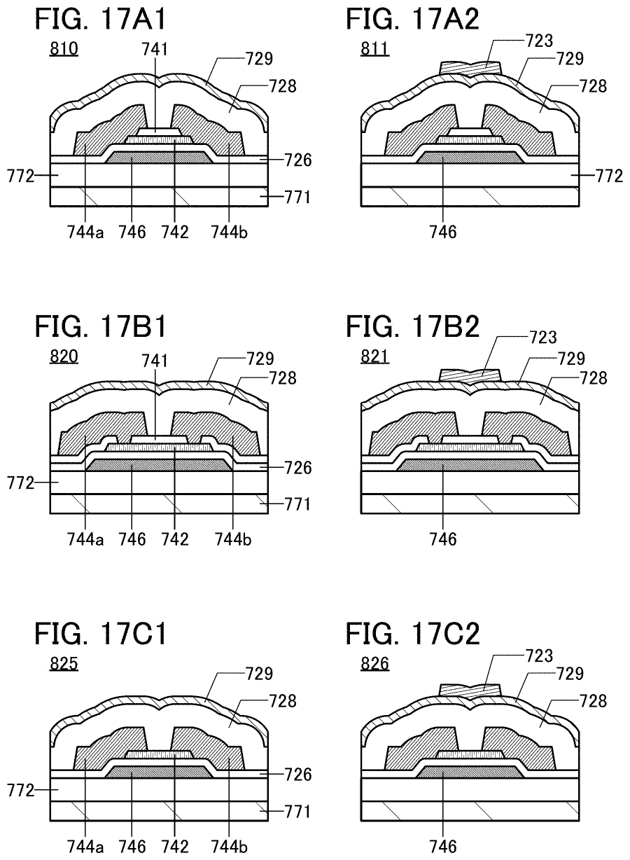

FIG. 17A1 is a cross-sectional view of a channel protective transistor 810 that is a type of bottom-gate transistor. In FIG. 17A1, the transistor 810 is formed over a substrate 771. The transistor 810 includes an electrode 746 over the substrate 771 with an insulating layer 772 therebetween. Furthermore, a semiconductor layer 742 is provided over the electrode 746 with an insulating layer 726 therebetween. The electrode 746 can function as a gate electrode. The insulating layer 726 can function as a gate insulating layer.

An insulating layer 741 is provided over a channel formation region in the semiconductor layer 742. An electrode 744a and an electrode 744b which are partly in contact with the semiconductor layer 742 are provided over the insulating layer 726. The electrode 744a can function as one of a source electrode and a drain electrode. The electrode 744b can function as the other of the source electrode and the drain electrode. Part of the electrode 744a and part of the electrode 744b are formed over the insulating layer 741.

The insulating layer 741 can function as a channel protective layer. With the insulating layer 741 provided over the channel formation region, the semiconductor layer 742 can be prevented from being exposed at the time of forming the electrode 744a and the electrode 744b. Thus, the channel formation region in the semiconductor layer 742 can be prevented from being etched at the time of forming the electrode 744a and the electrode 744b. According to one embodiment of the present invention, a transistor with favorable electrical characteristics can be achieved.

The transistor 810 includes an insulating layer 728 over the electrode 744a, the electrode 744b, and the insulating layer 741 and includes an insulating layer 729 over the insulating layer 728.

In the case where an oxide semiconductor is used for the semiconductor layer 742, a material capable of removing oxygen from part of the semiconductor layer 742 to generate oxygen vacancies is preferably used at least for regions of the electrode 744a and the electrode 744b that are in contact with the semiconductor layer 742. The carrier concentration in the regions of the semiconductor layer 742 where oxygen vacancies are generated is increased, so that the regions become n-type regions (n⁺ layers). Accordingly, the regions can function as a source region and a drain region. When an oxide semiconductor is used for the semiconductor layer 742, examples of the material capable of removing oxygen from the semiconductor layer 742 to generate oxygen vacancies include tungsten and titanium.

When the source region and the drain region are formed in the semiconductor layer 742, the contact resistance between the semiconductor layer 742, and the electrode 744a and the electrode 744b can be reduced. Accordingly, the electrical characteristics of the transistor, such as the field-effect mobility and the threshold voltage, can be improved.

In the case where a semiconductor such as silicon is used for the semiconductor layer 742, a layer that functions as an n-type semiconductor or a p-type semiconductor is preferably provided between the semiconductor layer 742 and the electrode 744a and between the semiconductor layer 742 and the electrode 744b. The layer that functions as an n-type semiconductor or a p-type semiconductor can function as a source region or a drain region in the transistor.

The insulating layer 729 is preferably formed using a material that has a function of preventing or reducing diffusion of impurities into the transistor from the outside. The insulating layer 729 can be omitted as necessary.

A transistor 811 shown in FIG. 17A2 is different from the transistor 810 in that an electrode 723 that can function as a back gate electrode is provided over the insulating layer 729. The electrode 723 can be formed using a material and a method similar to those of the electrode 746.

In general, a back gate electrode is formed using a conductive layer and positioned so that a channel formation region of a semiconductor layer is sandwiched between a gate electrode and the back gate electrode. Thus, the back gate electrode can function in a manner similar to that of the gate electrode. The potential of the back gate electrode may be equal to the potential of the gate electrode, or may be a ground potential (GND potential) or a given potential. Moreover, by changing the potential of the back gate electrode not in synchronization with but independently of the potential of the gate electrode, the threshold voltage of the transistor can be changed.

The electrode 746 and the electrode 723 can each function as a gate electrode. Thus, the insulating layer 726, the insulating layer 728, and the insulating layer 729 can each function as a gate insulating layer. The electrode 723 may be provided between the insulating layer 728 and the insulating layer 729.

In the case where one of the electrode 746 and the electrode 723 is referred to as a “gate electrode”, the other is referred to as a “back gate electrode”. For example, in the case where the electrode 723 in the transistor 811 is referred to as a “gate electrode”, the electrode 746 is referred to as a “back gate electrode”. In the case where the electrode 723 is used as a “gate electrode”, the transistor 811 can be considered as a type of top-gate transistor. In some case, one of the electrode 746 and the electrode 723 is referred to as a “first gate electrode”, and the other is referred to as a “second gate electrode”.

By providing the electrode 746 and the electrode 723 with the semiconductor layer 742 therebetween and setting the potential of the electrode 746 equal to the potential of the electrode 723, a region of the semiconductor layer 742 through which carriers flow is enlarged in the film thickness direction; thus, the number of transferred carriers is increased. As a result, the on-state current of the transistor 811 increases and the field-effect mobility increases.

Therefore, the transistor 811 is a transistor having a high on-state current for its occupied area. That is, the area occupied by the transistor 811 can be small for a required on-state current. According to one embodiment of the present invention, the area occupied by a transistor can be reduced. Therefore, according to one embodiment of the present invention, a semiconductor device having a high degree of integration can be provided.

The gate electrode and the back gate electrode are formed using conductive layers and thus each have a function of preventing an electric field generated outside the transistor from affecting the semiconductor layer in which the channel is formed (in particular, an electric field blocking function against static electricity or the like). When the back gate electrode is formed larger than the semiconductor layer such that the semiconductor layer is covered with the back gate electrode, the electric field blocking function can be enhanced.

When the back gate electrode is formed using a light-blocking conductive film, light can be prevented from entering the semiconductor layer from the back gate electrode side. Therefore, photodegradation of the semiconductor layer can be prevented and degradation in electrical characteristics of the transistor, such as a shift of the threshold voltage, can be prevented.

According to one embodiment of the present invention, a transistor with favorable reliability can be achieved. Moreover, a semiconductor device with favorable reliability can be achieved.

FIG. 17B1 shows a cross-sectional view of a channel-protective transistor 820 that is a type of bottom-gate transistor. The transistor 820 has substantially the same structure as the transistor 810 but is different from the transistor 810 in that the insulating layer 741 covers an end portion of the semiconductor layer 742. The semiconductor layer 742 is electrically connected to the electrode 744a in an opening portion formed by selectively removing part of the insulating layer 741 that overlaps with the semiconductor layer 742. The semiconductor layer 742 is electrically connected to the electrode 744b in another opening portion formed by selectively removing part of the insulating layer 741 that overlaps with the semiconductor layer 742. A region of the insulating layer 741 that overlaps with the channel formation region can function as a channel protective layer.

A transistor 821 shown in FIG. 17B2 is different from the transistor 820 in that the electrode 723 that can function as a back gate electrode is provided over the insulating layer 729.

With the insulating layer 741, the semiconductor layer 742 can be prevented from being exposed at the time of forming the electrode 744a and the electrode 744b. Thus, the semiconductor layer 742 can be prevented from being thinned at the time of forming the electrode 744a and the electrode 744b.

The distance between the electrode 744a and the electrode 746 and the distance between the electrode 744b and the electrode 746 in the transistor 820 and the transistor 821 are larger than those in the transistor 810 and the transistor 811. Thus, the parasitic capacitance generated between the electrode 744a and the electrode 746 can be reduced. Moreover, the parasitic capacitance generated between the electrode 744b and the electrode 746 can be reduced. According to one embodiment of the present invention, a transistor with favorable electrical characteristics can be achieved.

A transistor 825 shown in FIG. 17C1 is a channel-etched transistor that is a type of bottom-gate transistor. In the transistor 825, the electrode 744a and the electrode 744b are formed without the insulating layer 741. Thus, part of the semiconductor layer 742 that is exposed at the time of forming the electrode 744a and the electrode 744b is etched in some cases. Meanwhile, since the insulating layer 741 is not provided, the productivity of the transistor can be increased.

A transistor 826 shown in FIG. 17C2 is different from the transistor 820 in that the electrode 723 that can function as a back gate electrode is provided over the insulating layer 729.

### [Top-Gate Transistor]

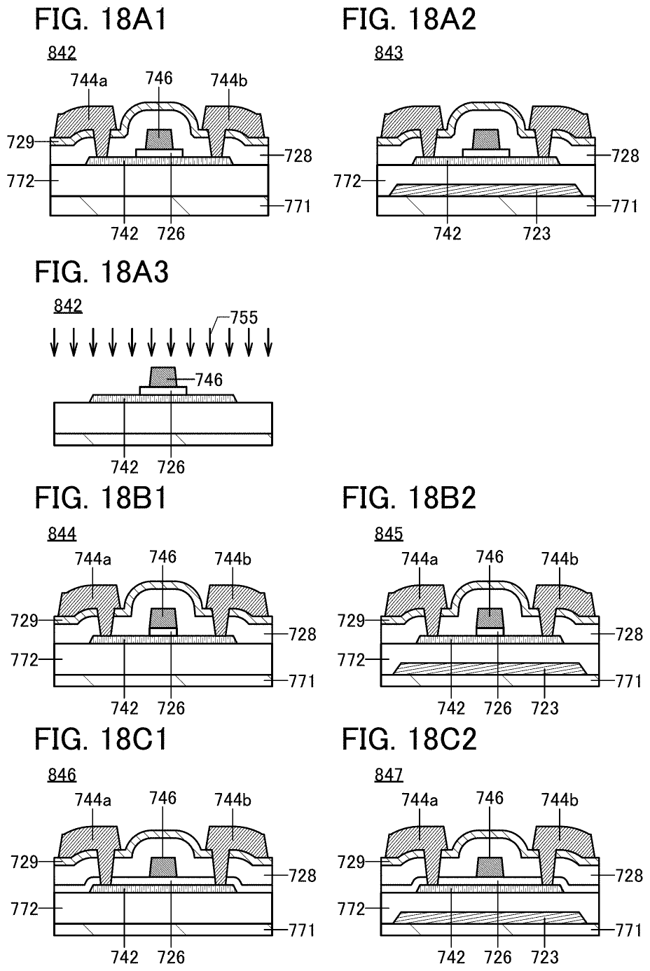

A transistor 842 shown as an example in FIG. 18A1 is a type of top-gate transistor. The transistor 842 is different from the transistor 810, the transistor 811, the transistor 820, the transistor 821, the transistor 825, and the transistor 826 in that the electrode 744a and the electrode 744b are formed after the formation of the insulating layer 729. The electrode 744a and the electrode 744b are electrically connected to the semiconductor layer 742 in opening portions formed in the insulating layer 728 and the insulating layer 729.

Part of the insulating layer 726 that does not overlap with the electrode 746 is removed, and the impurity 755 is introduced into the semiconductor layer 742 using the electrode 746 and the remaining part of the insulating layer 726 as a mask, so that an impurity region can be formed in the semiconductor layer 742 in a self-aligned manner (see FIG. 18A3). The transistor 842 includes a region where the insulating layer 726 extends beyond an end portion of the electrode 746. The semiconductor layer 742 in a region into which the impurity 755 is introduced through the insulating layer 726 has a lower impurity concentration than a region into which the impurity 755 is introduced without through the insulating layer 726. Thus, an LDD (Lightly Doped Drain) region is formed in a region of the semiconductor layer 742 that does not overlap with the electrode 746.

A transistor 843 shown in FIG. 18A2 is different from the transistor 842 in that the electrode 723 is included. The transistor 843 includes the electrode 723 that is formed over the substrate 771. The electrode 723 overlaps with the semiconductor layer 742 with the insulating layer 772 therebetween. The electrode 723 can function as a back gate electrode.

As in a transistor 844 shown in FIG. 18B1 and a transistor 845 shown in FIG. 18B2, the insulating layer 726 in a region that does not overlap with the electrode 746 may be completely removed. Alternatively, as in a transistor 846 shown in FIG. 18C1 and a transistor 847 shown in FIG. 18C2, the insulating layer 726 may be left.

Also in the transistor 842 to the transistor 847, the impurity 755 is introduced into the semiconductor layer 742 using the electrode 746 as a mask after the formation of the electrode 746, so that an impurity region can be formed in the semiconductor layer 742 in a self-aligned manner. According to one embodiment of the present invention, a transistor with favorable electrical characteristics can be achieved. Further, according to one embodiment of the present invention, a semiconductor device having a high degree of integration can be achieved.

At least part of this embodiment can be implemented in combination with the other embodiments described in this specification as appropriate.

### Embodiment 7

Described in this embodiment is a metal oxide (hereinafter also referred to as an oxide semiconductor) that can be used in an OS transistor described in the above embodiment.

The metal oxide preferably contains at least indium or zinc. In particular, indium and zinc are preferably contained. In addition, aluminum, gallium, yttrium, tin, or the like is preferably contained. Furthermore, one or more kinds selected from boron, silicon, titanium, iron, nickel, germanium, zirconium, molybdenum, lanthanum, cerium, neodymium, hafnium, tantalum, tungsten, magnesium, cobalt, and the like may be contained.

### <Classification of Crystal Structure>

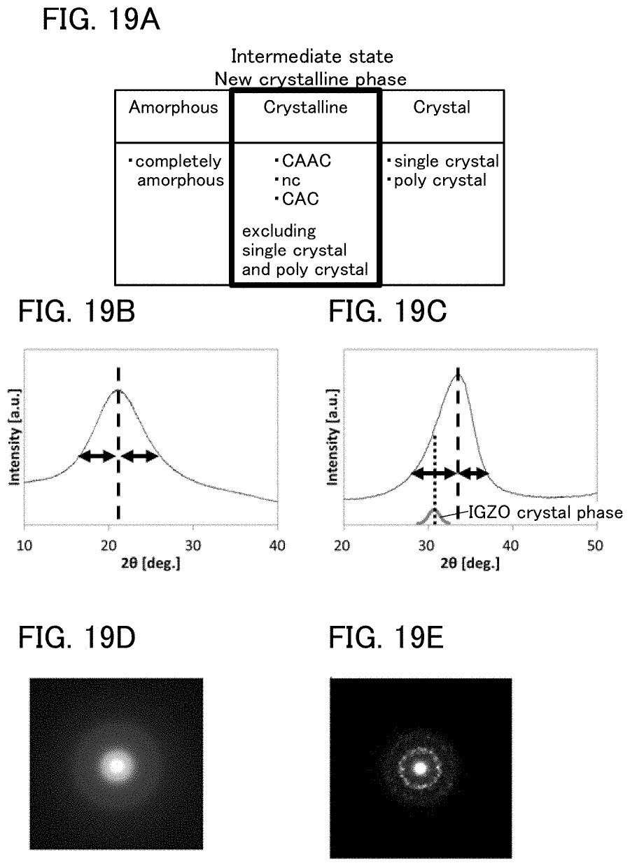

First, the classification of crystal structures of an oxide semiconductor is described with reference to FIG. 19A. FIG. 19A is a diagram showing the classification of crystal structures of an oxide semiconductor, typically IGZO (a metal oxide containing In, Ga, and Zn).

As shown in FIG. 19A, an oxide semiconductor is roughly classified into “Amorphous”, “Crystalline”, and “Crystal”. The term “Amorphous” includes completely amorphous. The term “Crystalline” includes CAAC (c-axis-aligned crystalline), nc (nanocrystalline), and CAC (cloud-aligned composite). Note that the term “Crystalline” excludes single crystal, poly crystal, and completely amorphous. The term “Crystal” includes single crystal and poly crystal.

Note that the structures in the thick frame in FIG. 19A are in an intermediate state between “Amorphous” and “Crystal”, and belong to a new crystalline phase. That is, these structures are completely different from “Amorphous”, which is energetically unstable, and “Crystal”.

A crystal structure of a film or a substrate can be analyzed with an X-ray diffraction (XRD) spectrum. Here, XRD spectra of a quartz glass substrate and an IGZO film having a crystal structure classified into “Crystalline” (also referred to as Crystalline IGZO), which are obtained by a GIXD (Grazing-Incidence XRD) measurement, are shown in FIG. 19B and FIG. 19C, respectively. Note that a GIXD method is also referred to as a thin film method or a Seemann-Bohlin method. The XRD spectrum that is shown in FIG. 19B and FIG. 19C and obtained by GIXD measurement is hereinafter simply referred to as an XRD spectrum. FIG. 19B shows an XRD spectrum of a quartz glass substrate, and FIG. 19C shows an XRD spectrum of a crystalline IGZO film. Note that the crystalline IGZO film shown in FIG. 19C has a composition in the vicinity of In:Ga:Zn=4:2:3 [atomic ratio]. Furthermore, the crystalline IGZO film shown in FIG. 19C has a thickness of 500 nm.

As indicated by arrows in FIG. 19B, the XRD spectrum of the quartz glass substrate shows a peak with a substantially bilaterally symmetrical shape. In contrast, as indicated by arrows in FIG. 19C, the XRD spectrum of the crystalline IGZO film shows a peak with a bilaterally asymmetrical shape. The asymmetrical peak of the XRD spectrum clearly shows the existence of crystal in the film or the substrate. In other words, the crystal structure of the film or the substrate cannot be regarded as “amorphous” unless it has a bilaterally symmetrical peak in the XRD spectrum. Note that in FIG. 19C, a crystal phase (IGZO crystal phase) is denoted at 2θ of 31° or in the vicinity thereof. The bilaterally asymmetrical peak of the XRD spectrum is probably attributed to a diffraction peak derived from such a crystal phase (a fine crystal).

Specifically, interference of an X-ray scattered by atoms contained in IGZO probably contributes to a peak at 2θ=34° or in the vicinity thereof. In addition, the fine crystal probably contributes to the peak at 2θ=31° or in the vicinity thereof. In the XRD spectrum of the crystalline IGZO film shown in FIG. 19C, the peak at 2θ of 34° or in the vicinity thereof is wide on the lower angle side. This indicates that the crystalline IGZO film includes a fine crystal attributed to the peak at 2θ of 31° or in the vicinity thereof.

A crystal structure of a film or a substrate can also be evaluated with a diffraction pattern obtained by a nanobeam electron diffraction (NBED) method (such a pattern is also referred to as a nanobeam electron diffraction pattern). Diffraction patterns of the quartz glass substrate and the IGZO film formed with a substrate temperature set at room temperature are shown in FIG. 19D and FIG. 19E, respectively. FIG. 19D shows the diffraction pattern of the quartz glass substrate and FIG. 19E shows the diffraction pattern of the IGZO film. Note that the IGZO film of FIG. 19E is formed by a sputtering method using an In—Ga—Zn oxide target with In:Ga:Zn=1:1:1 [atomic ratio]. In the nanobeam electron diffraction method, electron diffraction is performed with a probe diameter of 1 nm.

Note that as shown in FIG. 19D, a halo pattern is observed in the diffraction pattern of the quartz glass substrate, which indicates that the quartz glass substrate is in an amorphous state. As shown in FIG. 19E, not a halo pattern but a spot-like pattern is observed in the diffraction pattern of the IGZO film formed at room temperature. Thus, it is presumed that the IGZO film formed at room temperature is in an intermediate state, which is neither a crystal state nor an amorphous state, and it cannot be concluded that the IGZO film is in an amorphous state.

### <<Structure of Oxide Semiconductor>>

Oxide semiconductors might be classified in a manner different from that in FIG. 19A when classified in terms of the crystal structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, and a-like OS are described in detail.

### [CAAC-OS]

The CAAC-OS is an oxide semiconductor that has a plurality of crystal regions each of which has c-axis alignment in a particular direction. Note that the particular direction refers to the film thickness direction of a CAAC-OS film, the normal direction of the surface where the CAAC-OS film is formed, or the normal direction of the surface of the CAAC-OS film. The crystal region refers to a region having a periodic atomic arrangement. When an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the direction of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more fine crystals (crystals each of which has a maximum diameter of less than 10 nm). In the case where the crystal region is formed of one fine crystal, the maximum diameter of the crystal region is less than 10 nm. In the case where the crystal region is formed of a large number of fine crystals, the size of the crystal region may be approximately several tens of nanometers.

In the case of an In-M-Zn oxide (the element M is one or more kinds selected from aluminum, gallium, yttrium, tin, titanium, and the like), the CAAC-OS tends to have a layered crystal structure (also referred to as a stacked-layer structure) in which a layer containing indium (In) and oxygen (hereinafter, an In layer) and a layer containing the element M, zinc (Zn), and oxygen (hereinafter, an (M,Zn) layer) are stacked. Indium and the element M can be replaced with each other. Therefore, indium may be contained in the (M,Zn) layer. In addition, the element M may be contained in the In layer. Note that Zn may be contained in the In layer. Such a layered structure is observed as a lattice image in a high-resolution transmission electron microscope (TEM) image, for example.

When the CAAC-OS film is subjected to structural analysis by out-of-plane XRD measurement with an XRD apparatus using θ/2θ scanning, for example, a peak indicating c-axis alignment is detected at 2θ of 31° or in the vicinity thereof. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of the incident electron beam passing through a sample (also referred to as a direct spot) as the symmetric center.

When the crystal region is observed from the particular direction, a lattice arrangement in the crystal region is basically a hexagonal lattice arrangement; however, a unit lattice is not always a regular hexagon and is a non-regular hexagon in some cases. Furthermore, a pentagonal or heptagonal lattice arrangement, for example, is included in the distortion in some cases. Note that a clear grain boundary cannot be observed even in the vicinity of the distortion in the CAAC-OS. That is, formation of a crystal grain boundary is inhibited by the distortion of lattice arrangement. This is probably because the CAAC-OS can tolerate distortion owing to a low density of arrangement of oxygen atoms in the a-b plane direction, an interatomic bond distance changed by substitution of a metal atom, and the like.

A crystal structure in which a clear grain boundary is observed is what is called polycrystal. It is highly probable that the grain boundary becomes a recombination center and captures carriers and thus decreases the on-state current and field-effect mobility of a transistor, for example. Thus, the CAAC-OS in which no clear grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a grain boundary as compared with an In oxide.

The CAAC-OS is an oxide semiconductor with high crystallinity in which no clear grain boundary is observed. Thus, in the CAAC-OS, a reduction in electron mobility due to the grain boundary is less likely to occur. Moreover, since the crystallinity of an oxide semiconductor might be decreased by entry of impurities, formation of defects, or the like, the CAAC-OS can be regarded as an oxide semiconductor that has small amounts of impurities and defects (e.g., oxygen vacancies). Thus, an oxide semiconductor including the CAAC-OS is physically stable.

Therefore, the oxide semiconductor including the CAAC-OS is resistant to heat and has high reliability. In addition, the CAAC-OS is stable with respect to high temperatures in the manufacturing process (what is called thermal budget). Accordingly, the use of the CAAC-OS for the OS transistor can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a fine crystal. Note that the size of the fine crystal is, for example, greater than or equal to 1 nm and less than or equal to 10 nm, particularly greater than or equal to 1 nm and less than or equal to 3 nm; thus, the fine crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods. For example, when an nc-OS film is subjected to structural analysis by Out-of-plane XRD measurement with an XRD apparatus using θ/2 θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter larger than the diameter of a nanocrystal (e.g., larger than or equal to 50 nm). Meanwhile, in some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or smaller than the diameter of a nanocrystal (e.g., 1 nm or larger and 30 nm or smaller).

[a-like OS]

The a-like OS is an oxide semiconductor having a structure between the structure of the nc-OS and the structure of the amorphous oxide semiconductor. The a-like OS has a void or a low-density region. That is, the a-like OS has lower crystallinity than the nc-OS and the CAAC-OS. Moreover, the a-like OS has higher hydrogen concentration in the film than the nc-OS and the CAAC-OS.

### <<Structure of Oxide Semiconductor>>

Next, the above-described CAC-OS is described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state in which one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Note that the atomic ratios of In, Ga, and Zn to the metal elements contained in the CAC-OS in an In—Ga—Zn oxide are denoted by [In], [Ga], and [Zn], respectively. For example, [In] of the first region in the CAC-OS in the In—Ga—Zn oxide is higher than [In] in the composition of the CAC-OS film. Moreover, [Ga] of the second region is higher than [Ga] in the composition of the CAC-OS film. Alternatively, for example, the first region has higher [In] than the second region and lower [Ga] than the second region. Moreover, the second region has higher [Ga] than the first region and lower [In] than the first region.

Specifically, the first region includes indium oxide, indium zinc oxide, or the like as its main component. The second region includes gallium oxide, gallium zinc oxide, or the like as its main component. That is, the first region can be referred to as a region containing In as its main component. The second region can be referred to as a region containing Ga as its main component.

Note that a clear boundary between the first region and the second region cannot be observed in some cases.

In a material composition of a CAC-OS in an In—Ga—Zn oxide that contains In, Ga, Zn, and O, regions containing Ga as a main component are observed in part of the CAC-OS and regions containing In as a main component are observed in part thereof. These regions are randomly dispersed to form a mosaic pattern. Thus, it is suggested that the CAC-OS has a structure in which metal elements are unevenly distributed.

The CAC-OS can be formed by a sputtering method under a condition where a substrate is not heated intentionally, for example. Moreover, in the case of forming the CAC-OS by a sputtering method, any one or more selected from an inert gas (typically, argon), an oxygen gas, and a nitrogen gas are used as a deposition gas. The flow rate of the oxygen gas to the total flow rate of the deposition gas in deposition is preferably as low as possible; for example, the flow rate of the oxygen gas to the total flow rate of the deposition gas in deposition is higher than or equal to 0% and lower than 30%, preferably higher than or equal to 0% and lower than or equal to 10%.

For example, energy dispersive X-ray spectroscopy (EDX) is used to obtain EDX mapping, and according to the EDX mapping, the CAC-OS in the In—Ga—Zn oxide has a structure in which the region containing In as its main component (the first region) and the region containing Ga as its main component (the second region) are unevenly distributed and mixed.

Here, the first region has a higher conductivity than the second region. In other words, when carriers flow through the first region, the conductivity of a metal oxide is exhibited. Accordingly, when the first regions are distributed in a metal oxide as a cloud, high field-effect mobility (μ) can be achieved.

The second region has a higher insulating property than the first region. In other words, when the second regions are distributed in a metal oxide, leakage current can be inhibited.

Thus, in the case where a CAC-OS is used for a transistor, by the complementary function of the conducting function due to the first region and the insulating function due to the second region, the CAC-OS can have a switching function (On/Off function). A CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, high on-state current (Iₒₙ), high field-effect mobility (μ), and excellent switching operation can be achieved.

A transistor using a CAC-OS has high reliability. Thus, the CAC-OS is most suitable for a variety of semiconductor devices such as displays.

An oxide semiconductor has various structures with different properties. Two or more kinds among the amorphous oxide semiconductor, the polycrystalline oxide semiconductor, the a-like OS, the CAC-OS, the nc-OS, and the CAAC-OS may be included in an oxide semiconductor of one embodiment of the present invention.

### <Transistor Including Oxide Semiconductor>

Next, the case where the above oxide semiconductor is used for a transistor is described.

When the above oxide semiconductor is used for a transistor, a transistor with high field-effect mobility can be achieved. In addition, a transistor having high reliability can be achieved.

An oxide semiconductor having a low carrier concentration is preferably used for the transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm′. In order to reduce the carrier concentration of an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and accordingly has a low density of trap states in some cases.

Electric charge trapped by the trap states in the oxide semiconductor takes a long time to disappear and might behave like fixed electric charge. Thus, a transistor whose channel formation region is formed in an oxide semiconductor with a high density of trap states has unstable electrical characteristics in some cases.

Accordingly, in order to obtain stable electrical characteristics of a transistor, reducing impurity concentration in an oxide semiconductor is effective. In order to reduce the impurity concentration in the oxide semiconductor, it is preferable that the impurity concentration in an adjacent film be also reduced. Examples of impurities include hydrogen, nitrogen, an alkali metal, an alkaline earth metal, iron, nickel, and silicon.

### <Impurities>

Here, the influence of each impurity in the oxide semiconductor is described.

When silicon or carbon, which is one of Group 14 elements, is contained in the oxide semiconductor, defect states are formed in the oxide semiconductor. Thus, the concentration of silicon or carbon in the oxide semiconductor and the concentration of silicon or carbon in the vicinity of an interface with the oxide semiconductor (the concentration obtained by secondary ion mass spectrometry (SIMS)) are each set lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Accordingly, a transistor including an oxide semiconductor that contains an alkali metal or an alkaline earth metal tends to have normally-on characteristics. Thus, the concentration of an alkali metal or an alkaline earth metal in the oxide semiconductor, which is obtained by SIMS, is set lower than or equal to 1×10¹⁸ atoms/cm³, preferably lower than or equal to 2×10¹⁶ atoms/cm³.

An oxide semiconductor containing nitrogen easily becomes n-type by generation of electrons serving as carriers and an increase in carrier concentration. Thus, a transistor using an oxide semiconductor containing nitrogen as the semiconductor tends to have normally-on characteristics. When nitrogen is contained in the oxide semiconductor, a trap state is sometimes formed. This might make the electrical characteristics of the transistor unstable. Therefore, the concentration of nitrogen in the oxide semiconductor, which is obtained by SIMS, is set lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor containing hydrogen is likely to have normally-on characteristics. Accordingly, hydrogen in the oxide semiconductor is preferably reduced as much as possible. Specifically, the hydrogen concentration in the oxide semiconductor, which is obtained by SIMS, is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for the channel formation region of the transistor, stable electrical characteristics can be given.

At least part of this embodiment can be implemented in combination with the other embodiments described in this specification as appropriate.

### Embodiment 8

In this embodiment, examples of a product in which the semiconductor device or the display device described in the above embodiments is used for an electronic device will be described.

### <Laptop Personal Computer>

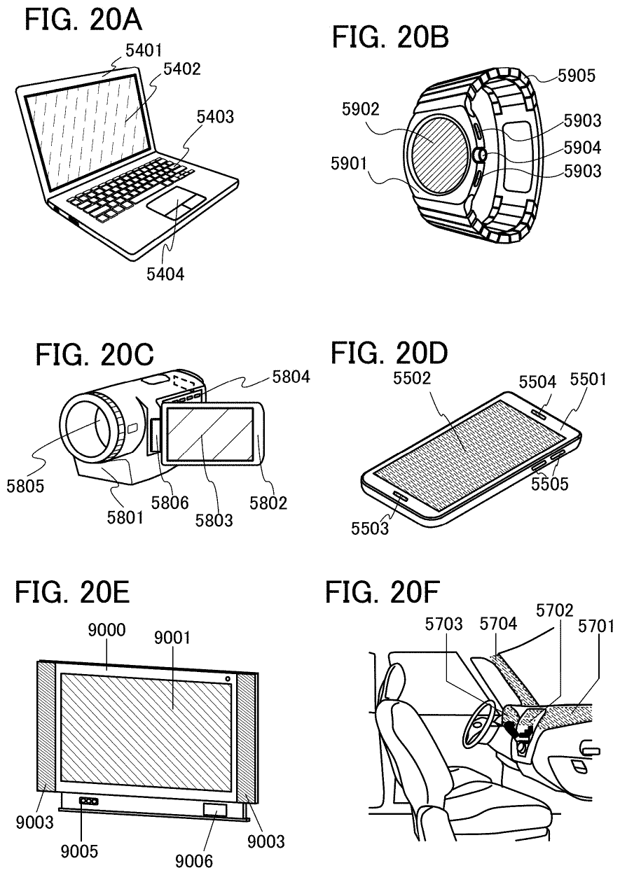

The semiconductor device or the display device of one embodiment of the present invention can be used for a display provided in an information terminal device. FIG. 20A is a laptop personal computer that is a kind of information terminal device, and includes a housing 5401, a display unit 5402, a keyboard 5403, a pointing device 5404, and the like.

### <Smart Watch>

The semiconductor device or the display device of one embodiment of the present invention can be used for a wearable terminal. FIG. 20B is a smart watch that is a kind of wearable terminal, and includes a housing 5901, a display unit 5902, operation buttons 5903, an operator 5904, a band 5905, and the like. A display device with a function of a position input device may be used for the display unit 5902. The function of the position input device can be added by provision of a touch panel in a display device. Alternatively, the function of the position input device can be added by provision of a photoelectric conversion element also called a photosensor in a pixel portion of a display device. As the operation buttons 5903, any of a power switch for activating the smart watch, a button for operating an application of the smart watch, a volume control button, a switch for turning on or off the display unit 5902, and the like can be provided. Although the smart watch shown in FIG. 20B includes two operation buttons 5903, the number of operation buttons included in the smart watch is not limited thereto. The operator 5904 functions as a crown used for setting the time on the smart watch. The operator 5904 may be used as an input interface for operating an application of the smart watch as well as the crown for time adjustment. Although the smart watch shown in FIG. 20B includes the operator 5904, one embodiment of the present invention is not limited thereto and does not necessarily include the operator 5904.

### <Video Camera>

The semiconductor device or the display device of one embodiment of the present invention can be used for a video camera. A video camera shown in FIG. 20C includes a first housing 5801, a second housing 5802, a display unit 5803, operation keys 5804, a lens 5805, a joint 5806, and the like. The operation keys 5804 and the lens 5805 are provided in the first housing 5801, and the display unit 5803 is provided in the second housing 5802. The first housing 5801 and the second housing 5802 are connected to each other with the joint 5806, and the angle between the first housing 5801 and the second housing 5802 can be changed with the joint 5806. Images on the display unit 5803 may be changed in accordance with the angle at the joint 5806 between the first housing 5801 and the second housing 5802.

### <Mobile Phone>

The semiconductor device or the display device of one embodiment of the present invention can be used for a mobile phone. FIG. 20D is a mobile phone having a function of an information terminal, and includes a housing 5501, a display unit 5502, a microphone 5503, a speaker 5504, and operation buttons 5505. A display device with a function of a position input device may be used for the display unit 5502. The function of the position input device can be added by provision of a touch panel in a display device. Alternatively, the function of the position input device can be added by provision of a photoelectric conversion element also called a photosensor in a pixel portion of a display device. As the operation buttons 5505, any of a power switch for activating the mobile phone, a button for operating an application of the mobile phone, a volume control button, a switch for turning on or off the display unit 5502, and the like can be provided.

Although the mobile phone shown in FIG. 20D includes two operation buttons 5505, the number of operation buttons included in the mobile phone is not limited thereto. Although not illustrated, the mobile phone shown in FIG. 20D may include a light-emitting device used for a flashlight or a lighting purpose.

### <Television Device>

The semiconductor device or the display device of one embodiment of the present invention can be used for a television device. FIG. 20E shows a television device including a housing 9000, a display unit 9001, a speaker 9003, an operation key 9005 (including a power switch or an operation switch), a connection terminal 9006, and the like. The television device can include the display unit 9001 having a large screen size of 50 inches or more or 100 inches or more, for example.

### <Vehicle>

The semiconductor device or the display device of one embodiment of the present invention can be used around a driver's seat in a car, which is a vehicle.

For example, FIG. 20F shows a windshield and its vicinity inside a car. FIG. 20F shows a display panel 5701, a display panel 5702, and a display panel 5703 that are attached to a dashboard and a display panel 5704 that is attached to a pillar.

The display panel 5701 to the display panel 5703 can provide a variety of kinds of information by displaying navigation information, a speedometer, a tachometer, a mileage, a fuel meter, a gearshift indicator, and air-condition setting. Items shown on the display panel, their layout, and the like can be changed as appropriate to suit the user's preferences, resulting in more sophisticated design. The display panel 5701 to the display panel 5703 can also be used as lighting devices.

The display panel 5704 can compensate for the view obstructed by the pillar (blind areas) by showing an image taken by an imaging unit provided for the car body. That is, displaying an image taken by the imaging unit provided on the outside of the car body compensates for blind areas and improves safety. Moreover, showing an image to compensate for the area that a driver cannot see allows confirming the safety more naturally and comfortably. The display panel 5704 can also be used as a lighting device.

### <Electronic Device for Electronic Public Notice>

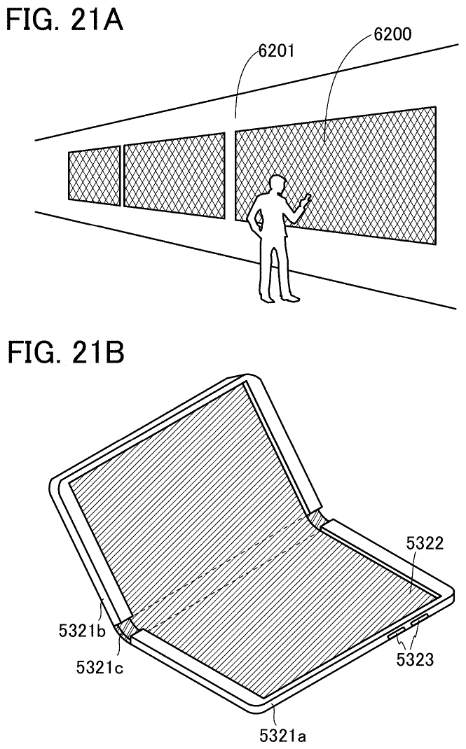

The semiconductor device or the display device of one embodiment of the present invention can be used for a display used for an electronic public notice. FIG. 21A shows an example of digital signage that can be attached to a wall. FIG. 21A shows a digital signage 6200 attached to a wall 6201.

### <Foldable Tablet Information Terminal>

The semiconductor device or the display device of one embodiment of the present invention can be used for a tablet information terminal. FIG. 21B shows a tablet information terminal with a foldable structure. The information terminal shown in FIG. 21B includes a housing 5321a, a housing 5321b, a display unit 5322, and operation buttons 5323. In particular, the display unit 5322 includes a flexible base and the base allows a foldable structure to be achieved.

The housing 5321a and the housing 5321b are connected to each other with a hinge portion 5321c that allows the display unit 5322 to be folded in half. The display unit 5322 is provided in the housing 5321a, the housing 5321b, and the hinge portion 5321c.

Although not illustrated, each of the electronic devices shown in FIG. 20A to FIG. 20C, FIG. 20E, FIG. 21A, and FIG. 21B may have a structure with a microphone and a speaker. The electronic devices with this structure can have an audio input function, for example.

Although not illustrated, each of the electronic devices shown in FIG. 20A, FIG. 20B, FIG. 20D, FIG. 21A, and FIG. 21B may have a structure with a camera.

Although not illustrated, each of the electronic devices shown in FIG. 20A to FIG. 20F, FIG. 21A, and FIG. 21B may have a structure with a sensor (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, infrared rays, or the like) in the housing. In particular, when the mobile phone shown in FIG. 20D is provided with a sensing device which includes a sensor for sensing inclinations, such as a gyroscope sensor or an acceleration sensor, the orientation of the mobile phone (the orientation of the mobile phone with respect to the vertical direction) is determined and display on the screen of the display unit 5502 can be automatically changed in accordance with the orientation of the mobile phone.

Although not illustrated, each of the electronic devices shown in FIG. 20A to FIG. 20F, FIG. 21A, and FIG. 21B may have a structure with a device for obtaining biological information such as fingerprints, veins, iris, or voice prints. Employing this structure can achieve an electronic device having a biometric identification function.

A flexible base may be used for the display unit of each of the electronic devices shown in FIG. 20A to FIG. 20E and FIG. 21A. Specifically, the display unit may have a structure in which a transistor, a capacitor, a display element, and the like are provided over a flexible base. Employing this structure can achieve not only the electronic device having the housing with a flat surface as shown in FIG. 20A to FIG. 20E and FIG. 21A but also an electronic device having a housing with a curved surface like the dashboard and the pillar shown in FIG. 20F.

As a flexible base that can be used for the display units in FIG. 20A to FIG. 20F, FIG. 21A, and FIG. 21B, any of the following materials that transmit visible light can be used, for example: a poly(ethylene terephthalate) resin (PET), a poly(ethylene naphthalate) resin (PEN), a poly(ether sulfone) resin (PES), a polyacrylonitrile resin, an acrylic resin, a polyimide resin, a poly(methyl methacrylate) resin, a polycarbonate resin, a polyamide resin, a polycycloolefin resin, a polystyrene resin, a poly(amide imide) resin, a polypropylene resin, a polyester resin, a poly(vinyl halide) resin, an aramid resin, an epoxy resin, and the like. Alternatively, a mixture or a stack of these materials may be used.

At least part of this embodiment can be implemented in combination with the other embodiments described in this specification as appropriate.

### REFERENCE NUMERALS

100: electronic device, 101: housing, 102: display unit, 103: camera, 104: illuminance sensor, 105: speaker, 106: power button, 107: operation button, 108: microphone, 150: user, DD: display device, PA: display unit, GD: gate driver circuit, SD: source driver circuit, PIX: pixel, SR: shift register, LAT: latch circuit, LVS: level shifter circuit, DAC: digital-analog converter circuit, AMP: amplifier circuit, GL: wiring, DL: wiring, DB: data bus wiring, Tr1 to Tr7: transistor, C1, C2, C3: capacitor, LD: light-emitting element, GL1 to GL4: wiring, DL: wiring, WDL: wiring, VL: wiring, AL: wiring, CAT: wiring, ND1: node, ND2: node

1. A device comprising a display unit, an imaging unit, and an illuminance sensing unit, the device comprising:
a function of detecting that a user sees the display unit by the imaging unit;
a function of measuring external illuminance by the illuminance sensing unit in the case where the user sees the display unit; and
a function of determining a correction value of a display luminance in accordance with a value of the measured external illuminance and displaying an image on the display unit with a luminance based on the correction value.

2. The device according to claim 1, further comprising:
a function of sensing part or the whole of a user's face by the imaging unit;
a function of estimating a user's emotion from data of the part or the whole of the user's face sensed; and
a function of supplying data by the display unit in accordance with the estimated emotion.

3. The device according to claim 2, further comprising:
an audio output unit, and
a function of supplying audio data by the audio output unit in accordance with the estimated emotion.

4. A driving method of an electronic device comprising a display unit, an imaging unit, and an illuminance sensing unit, comprising:
a first step of determining if a user sees the display unit by the imaging unit;
a second step of measuring external illuminance by the illuminance sensing unit when it is determined that the user sees the display unit;
a third step of determining from a value of the measured external illuminance whether display luminance is to be corrected;
a fourth step of displaying an image with a predetermined luminance in the case where the display luminance is determined not to be corrected in the third step;
a fifth step of determining a correction value in the case where the display luminance is determined to be corrected in the third step; and
a sixth step of displaying an image with a corrected luminance based on the correction value determined in the fifth step.

5. The driving method of an electronic device according to claim 4, further comprising:
a seventh step of turning off display of the display unit when it is determined that the user does not see the display unit in the first step.

6. The driving method of an electronic device according to claim 4,
wherein the display unit comprises a display device,
wherein the display device comprises a pixel,
wherein the pixel comprises a display element,
wherein the pixel comprises:
a function of retaining a first voltage based on an input first pulse signal; and
a function of driving the display element with a third voltage obtained by adding the first voltage and a second voltage based on an input second pulse signal, and
wherein the first pulse signal is determined in accordance with the correction value.

7. The driving method of an electronic device according to claim 6,
wherein the display element is a light-emitting element, and
wherein the light-emitting element emits light with a luminance based on the third voltage.

8. The driving method of an electronic device according to claim 7,
wherein the light-emitting element is an organic EL element.

9. The driving method of an electronic device according to claim 7,
wherein the light-emitting element is a light-emitting diode.

10. The driving method of an electronic device according to claim 6,
wherein the display element is a liquid crystal element, and
wherein alignment of a liquid crystal in the liquid crystal element changes with the third voltage.

11. The driving method of an electronic device according to claim 6,
wherein the electronic device comprises a first driver circuit supplying the first pulse signal, and
wherein a first power supply voltage for generating the first pulse signal in the first driver circuit is lower than a maximum value of the third voltage.

12. The driving method of an electronic device according to claim 10,
wherein the electronic device comprises a first driver circuit supplying the first pulse signal, and
wherein a first power supply voltage for generating the first pulse signal in the first driver circuit is lower than a maximum value of the third voltage.
